(19) United States
(12) Patent Application Publication
(10) Pub. No.: US 2024/0395652 A1
(43) Pub. Date: Nov. 28, 2024

(54) PACKAGE STRUCTURE INCLUDING A PACKAGE LID HAVING A PATTERNED BOTTOM SURFACE AND METHODS OF FORMING THE SAME

(71) Applicant: Taiwan Semiconductor Manufacturing Company Limited, Hsinchu (TW)

(72) Inventors: Yu-Wei Lin, New Taipei City (TW); Meng-Hsuan Hsiao, Hsinchu City (TW); Sih-Hao Liao, New Taipei City (TW); Ming Shih Yeh, Zhubei City (TW)

(21) Appl. No.: 18/321,129

(22) Filed: May 22, 2023

(51) Int. Cl. H01L 23/367; H01L 23/00; H01L 23/053; H01L 23/42

(52) U.S. Cl. CPC H01L 23/367; H01L 23/053; H01L 23/42; H01L 24/32; H01L 24/83; H01L 2224/32245; H01L 2224/83201

(57) ABSTRACT

A package structure includes a package substrate, a package module on the package substrate, a thermal interface material (TIM) layer on the package module, and a package lid on the TIM layer. The package lid includes a package lid foot portion attached to the package substrate, and a package lid plate portion on the package lid foot portion and including a patterned bottom surface having a plurality of recessed portions, wherein at least a portion of the TIM layer is located in the plurality of recessed portions.

### BACKGROUND

In semiconductor packaging, a thermal interface material (TIM) layer may be located between a package module (e.g., semiconductor device) and package lid (e.g., heat sink). The TIM layer may improve thermal contact by filling the microscopic gaps and irregularities between the surfaces. A phenomenon called “pump-out” may sometimes occur, in which the TIM layer is displaced from the interface, causing a loss of thermal contact and reduced heat transfer efficiency.

Pump-out of the TIM layer in a package structure may occur in different ways, including lateral flow (the TIM layer may flow laterally away from the interface due to shear forces caused by thermal cycling), vertical flow (the TIM layer may flow vertically away from the interface due to pressure differences caused by thermal cycling), extrusion (the TIM layer may be extruded from the interface due to mechanical stresses caused by differential thermal expansion between the TIM layer, package module and package lid), and evaporation (the volatile components of the TIM layer may evaporate, causing the TIM layer to shrink and lose its thermal contact with the interface).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a package structure according to one or more embodiments.

FIG. 1B is a plan view (e.g., top-down view) of the package structure according to one or more embodiments.

FIG. 1C is a detailed vertical cross-sectional view of the TIM layer in the package structure according to one or more embodiments.

FIG. 2A is a plan view (e.g., top-down view) of the underside of the package lid plate portion, according to one or more embodiments.

FIG. 2B is a detailed plan view (e.g., top-down view) of the underside of the package lid plate portion, according to one or more embodiments.

FIG. 3 illustrates a stamping process of forming the patterned bottom surface of the package lid according to one or more embodiments.

FIGS. 4A-4I illustrates various protrusion pads that may be used in the stamping process according to one or more embodiments.

FIG. 5A is a vertical cross-sectional view of an intermediate structure including the package substrate having package substrate upper bonding pads and package substrate lower bonding pads, according to one or more embodiments.

FIG. 5B illustrates a vertical cross-sectional view of an intermediate structure in which the package module may be mounted on the package substrate, according to one or more embodiments.

FIG. 5C illustrates a vertical cross-sectional view of an intermediate structure in which the package underfill layer may be formed on the package substrate according to one or more embodiments.

FIG. 5D illustrates a vertical cross-sectional view of an intermediate structure in which the SMDs may be mounted on the package substrate, according to one or more embodiments.

FIG. 5E illustrates a vertical cross-sectional view of an intermediate structure in which the TIM layer may be attached to (e.g., formed on) the package module according to one or more embodiments.

FIG. 5F illustrates a vertical cross-sectional view of an intermediate structure in which the adhesive layer may be applied to the package substrate according to one or more embodiments.

FIG. 5G illustrates a vertical cross-sectional view of an intermediate structure in which the package lid may be attached to (e.g., mounted on) the package substrate according to one or more embodiments.

FIG. 5H illustrates a vertical cross-sectional view of an intermediate structure in which a plurality of solder balls may be formed on the package substrate according to one or more embodiments.

FIG. 6 is a flow chart illustrating a method of forming the package structure according to one or more embodiments.

FIG. 7 is a vertical cross-sectional view of a package structure having a first alternative design, according to one or more embodiments.

FIG. 8 is a vertical cross-sectional view of a package structure having a second alternative design, according to one or more embodiments.

FIG. 9 is a vertical cross-sectional view of a package structure having a third alternative design, according to one or more embodiments.

FIG. 10 is a vertical cross-sectional view of a package structure having a fourth alternative design, according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Pump-out of the TIM layer may be especially problematic when the TIM layer has a low melting point. In such instances, a temperature of the package structure may increase in instances in which the package structure is powered on, causing the TIM layer to melt (e.g., local phase changing or local melting) and turn to liquid at a hot spot (e.g., silicon hot spot). Such conditions may induce pump-out failure of the package structure in which the melted TIM layer may pump out of a space between a package lid and a package module.

Pump-out may lead to increased thermal resistance (e.g., interfacial thermal resistance) and temperature rise, which may affect the reliability and performance of the package structure. To mitigate the problem, various techniques may be used, including the use of more stable and resilient materials in the TIM layer, optimizing the thickness and composition of the TIM layer, and applying a mechanical force to maintain the TIM layer in place.

One or more embodiments of the present disclosure may include a package structure (e.g., a high-performance package structure) and a package lid. The package structure may include a package substrate and a package module on the package substrate. The package structure may also include, for example, a flip chip-chip scale package (FC-CSP) design, a three-dimensional integrated package design (e.g., fan-out design), and so on. A thermal interface material (TIM) layer may be located (e.g., integrated) between the package module (e.g., silicon die) and the package lid to improve heat dissipation. The TIM layer may include, for example, a grease type TIM layer, a gel type TIM layer, graphite film TIM layer, a liquid metal TIM layer (e.g., a gallium-rich TIM layer), a PCM type TIM layer, etc. The PCM type TIM layer may include, for example, a polymer-based PCM TIM layer or a low-melting-temperature metal TIM layer. The PCM type TIM layer may improve void and delamination issues, enhance thermal contact resistance and improve thermal performance in a package structure, compared to other materials of the TIM layer. In at least one embodiment, the PCM type TIM layer may change its phase from solid to high viscosity semi liquid around 60° C.

A package lid (e.g., heat spreader) may be attached to the package substrate over the package module. The package lid may be made of a ceramic, polymer or metal such as copper, nickel, etc. The package lid may help to inhibit (e.g., minimize) warpage of the package structure.

The package lid may include a patterned bottom surface. In at least one embodiment, the patterned bottom surface may include a honeycomb design. In at least one embodiment, the patterned bottom surface may include a plurality of recessed portions. In at least one embodiment, a shape of the recessed portions may include a hexagon, square, octagon, round, oval, capsule, ladder-shape, etc. The patterned bottom surface may contact a TIM layer on a package module in the package structure. An area of the patterned bottom surface (e.g., honeycomb region area) may substantially correspond to (e.g., substantially be aligned with) an area of the package module (e.g., a chip on wafer (CoW) area, InFO die area, etc.). A depth of the recessed portions of the patterned bottom surface (e.g., honeycomb depth) may be in a range from about 0.2 times to 0.8 times (e.g., about 0.5 times) a thickness of the TIM layer (e.g., an incoming thickness of the TIM layer).

The patterned bottom surface (e.g., honeycomb design) of the package lid may help inhibit pump-out of the TIM layer. In at least one embodiment the package structure may include a PCM type TIM layer providing a good heat dissipation performance, and the patterned bottom surface may help inhibit pump-out at a hot spot of a silicon die in the package module of the package structure. The patterned bottom surface may also increase a contact area between the package lid and the TIM layer and enhance an interfacial thermal conductance. The patterned bottom surface may also provide extra spacing between the package lid and the package module which may help to inhibit the TIM layer from bleeding out of the space. In at least one embodiment the package structure may include one or more surface mount devices (SMDs) on the package substrate adjacent the package module. In that case, the patterned bottom surface may help to inhibit the TIM layer from bleeding out and touching the SMD which may cause an electrical failure in the package structure.

Thus, the package structure having the package lid with a patterned bottom surface (e.g., honeycomb design) may have several advantages and benefits. In particular, the package structure may help to inhibit pump-out of the TIM layer and thereby reduce a pump-out risk. The patterned bottom surface of the package lid may also increase a contact surface area between the package lid and the TIM layer and thereby help to provide good heat dissipation. The patterned bottom surface of the package lid may also provide extra spacing to prevent TIM layer pump-out/bleeding.

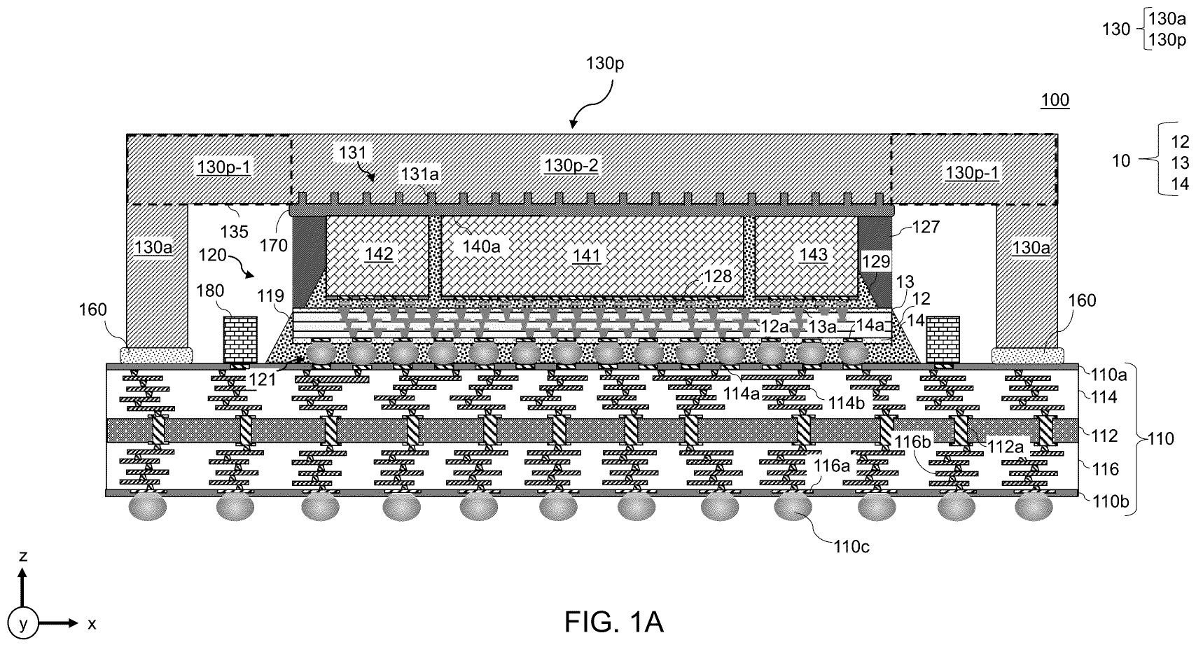

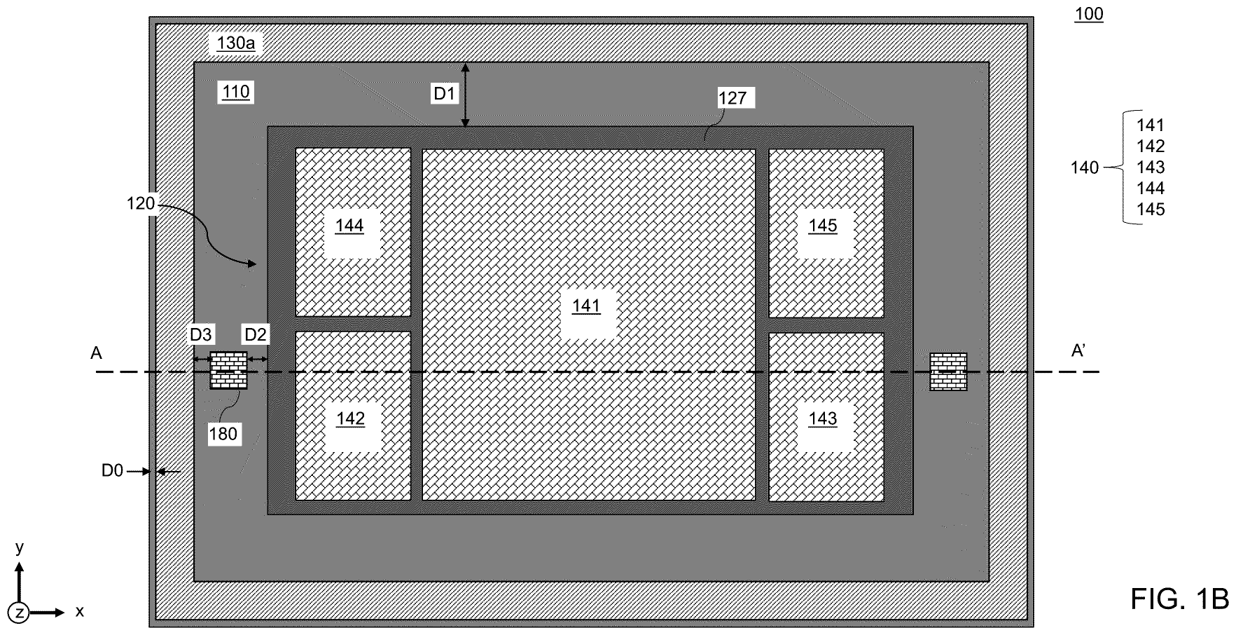

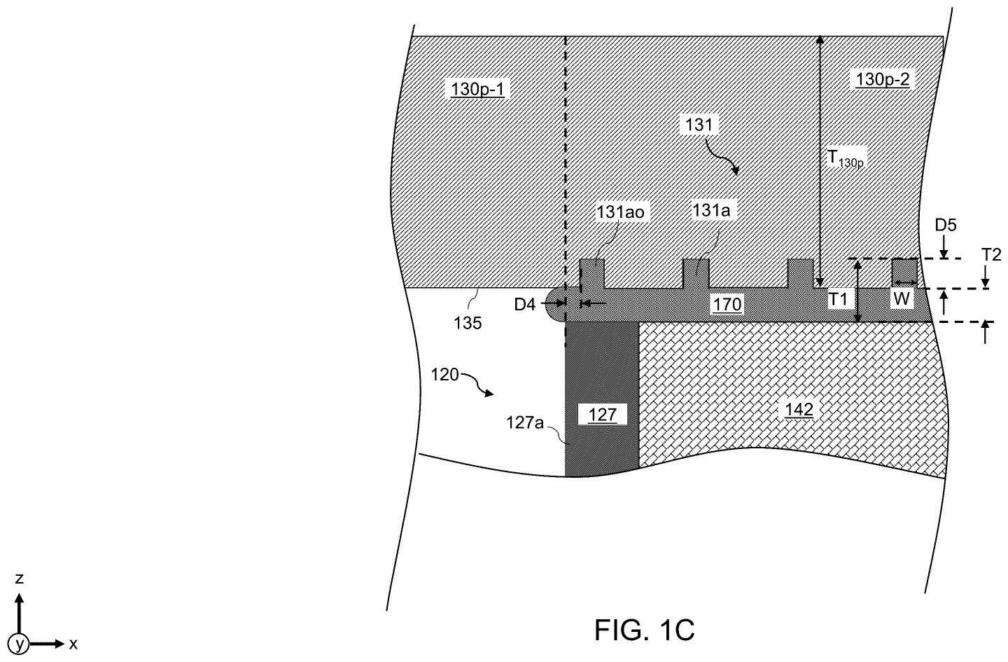

FIG. 1A is a vertical cross-sectional view of a package structure 100 according to one or more embodiments. FIG. 1B is a plan view (e.g., top-down view) of the package structure 100 according to one or more embodiments. The vertical cross-sectional view in FIG. 1A is along the line A-A′ in FIG. 1B. FIG. 1C is a detailed vertical cross-sectional view of the TIM layer 170 in the package structure 100 according to one or more embodiments.

As illustrated in FIG. 1A, the package structure 100 may include a package substrate 110, the package module 120 on the package substrate 110, and a package lid 130 on the package module 120. The package lid 130 may include a package lid plate portion 130p having an underside 135 with a patterned bottom surface 131. The patterned bottom surface 131 may help to reduce a risk of TIM layer pump-out in the package structure 100.

The package substrate 110 may include a cored or coreless substrate. In at least one embodiment, for example, the package substrate 110 may include a core 112, a package substrate upper dielectric layer 114 formed on the core 112 (e.g., a first side or chip-side of the package substrate 110), and a package substrate lower dielectric layer 116 formed on the core 112 (e.g., a second side or board-side of the package substrate 110). In particular, the package substrate 110 may include a build-up film substrate such as an Ajinomoto build-up film (ABF) substrate. That is, in at least one embodiment, each of the package substrate upper dielectric layer 114 and the package substrate lower dielectric layer 116 may be described as an ABF layer.

The core 112 may help to provide rigidity to the package substrate 110. The core 112 may include, for example, an epoxy resin such as a bismaleimide triazine epoxy (BT epoxy) and/or a woven glass laminate. The core 112 may alternatively or in addition include an organic material such as a polymer material. In particular, the core 112 may include a dielectric polymer material such as polyimide (PI), benzocyclobutene (BCB) polymer, or polybenzobisoxazole (PBO). Other suitable dielectric materials are within the contemplated scope of disclosure.

The core 112 may include one or more through vias 112a. The through vias 112a may extend from a lower surface of the core 112 to an upper surface of the core 112. The through vias 112a may allow an electrical connection between the package substrate upper dielectric layer 114 and the package substrate lower dielectric layer 116. The through vias 112a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate upper dielectric layer 114 may be formed on an upper surface of the core 112. The package substrate upper dielectric layer 114 may include a plurality of layers and, in particular, may include a build-up film (e.g., ABF). The package substrate upper dielectric layer 114 may also include an organic material such as a polymer material. In particular, the package substrate upper dielectric layer 114 may include a dielectric polymer material such as polyimide (PI), benzocyclobutene (BCB), or polybenzobisoxazole (PBO). Other suitable dielectric materials are within the contemplated scope of disclosure.

The package substrate upper dielectric layer 114 may include one or more package substrate upper bonding pads 114a on a chip-side surface of the package substrate upper dielectric layer 114. The package substrate upper bonding pads 114a may be exposed on the chip-side surface of the package substrate upper dielectric layer 114. The package substrate upper dielectric layer 114 may also include one or more metal interconnect structures 114b. The metal interconnect structures 114b may be connected to the package substrate upper bonding pads 114a and the through vias 112a in the core 112. The metal interconnect structures 114b may include metal layers (e.g., copper traces) and metal vias connecting the metal layers. The package substrate upper bonding pads 114a and the metal interconnect structures 114b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate upper passivation layer 110a may be formed on the chip-side surface of the package substrate upper dielectric layer 114. The package substrate upper passivation layer 110a may partially cover the package substrate upper bonding pads 114a. The upper passivation layer 110a may include silicon oxide, silicon nitride, low-k dielectric materials such as carbon-doped oxides, extremely low-k dielectric materials such as porous carbon doped silicon dioxide, a combination thereof or other suitable material.

The package substrate lower dielectric layer 116 may be formed on an lower surface of the core 112. The package substrate lower dielectric layer 116 may also include a plurality of layers and, in particular, may include a build-up film (e.g., ABF). The package substrate lower dielectric layer 116 may also include an organic material such as a polymer material. In particular, the package substrate lower dielectric layer 116 may include a dielectric polymer material such as polyimide (PI), benzocyclobutene (BCB), or polybenzobisoxazole (PBO). Other suitable dielectric materials are within the contemplated scope of disclosure.

The package substrate lower dielectric layer 116 may include one or more package substrate lower bonding pads 116a on a board-side surface of the package substrate lower dielectric layer 116. In particular, the package substrate lower bonding pads 116a may be exposed on the board-side surface of the package substrate lower dielectric layer 116. The package substrate lower dielectric layer 116 may also include one or more metal interconnect structures 116b. The metal interconnect structures 116b may be connected to the package substrate lower bonding pads 116a and the through vias 112a in the core 112. The metal interconnect structures 116b may include metal layers (e.g., copper traces) and metal vias connecting the metal layers. The package substrate lower bonding pads 116a and the metal interconnect structures 116b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate lower passivation layer 110b may be formed on the board-side surface of the package substrate lower dielectric layer 116. The package substrate lower passivation layer 110b may partially cover the package substrate lower bonding pads 116a. The package substrate lower passivation layer 110b may include silicon oxide, silicon nitride, low-k dielectric materials such as carbon-doped oxides, extremely low-k dielectric materials such as porous carbon doped silicon dioxide, a combination thereof or other suitable material.

A ball-grid array (BGA) including a plurality of solder balls 110c may be formed on the board-side surface of the package substrate lower dielectric layer 116. The solder balls 110c may allow the package structure 100 to be securely mounted on a substrate such as a printed circuit board (PCB) and electrically coupled to the PCB substrate. The solder balls 110c may contact the package substrate lower bonding pads 116a, respectively. The solder balls 110c may therefore be electrically connected to the package substrate upper bonding pads 114a by way of metal interconnect structures 116b, the through vias 112a and the metal interconnect structures 114b.

The package module 120 may include an interposer 10 and one or more semiconductor dies 140 (see FIG. 1B) on the interposer 10. The package module 120 is not limited to any particular configuration. The package module 120 may include, for example, a flip chip-chip scale package (FC-CSP) design, a chip-on-wafer-on-substrate (CoWoS®) design, an integrated fan-out (InFO_oS) design, and so on. In at least one embodiment, the interposer 10 may be omitted from the package module 120. In such embodiments, the semiconductor dies 140 may be attached directly to the package substrate 110.

The package module 120 may be bonded to and electrically coupled to the package substrate 110 by the C4 bumps 121 on the board-side surface of the interposer 10. In particular, the C4 bumps 121 may be formed on lower bonding pads 14a on a board-side surface of the interposer 10, respectively. The C4 bumps 121 may be bonded to the package substrate upper bonding pads 114a of the package substrate 110 using solder reflow, compression bonding, thermocompression bonding, etc. In at least one embodiment, the C4 bumps 121 may include underbump metallurgy (UBM) layers on the lower bonding pads 14a and the package substrate upper bonding pads 114a. The C4 bumps 121 may further include a contact pad (e.g., copper/nickel contact pad) on the UBM layers and a solder bump (e.g., SnAg solder bump) on the contact pad.

As illustrated in FIG. 1A, the package substrate 110 may have a length in the x-direction that is greater than a length of the package module 120 in the x-direction. The package substrate 110 may also have a width in the y-direction that is greater than a width of the package module 120 in the y-direction.

A package underfill layer 119 may be formed on the package substrate 110 under and around the package module 120. The package underfill layer 119 may also be formed around the C4 bumps 121. The package underfill layer 119 may thereby securely fix the package module 120 to the package substrate 110. The package underfill layer 119 may be formed of an epoxy-based polymeric material.

The interposer 10 is not necessarily limited to any particular materials or configuration. The interposer 10 may include, for example, organic material (e.g., dielectric polymer), inorganic material (e.g., silicon), glass substrate, etc. In at least one embodiment, the interposer 10 may include a plurality of polymer layers 12 and a plurality of redistribution layers 12a stacked alternately. The number of the polymer layers 12 and/or the number of redistribution layers 12a in the interposer 10 are not limited by the disclosure.

In at least one embodiment, the polymer layers 12 may include, for example, polyimide (PI), epoxy resin, acrylic resin, phenol resin, benzocyclobutene (BCB), polybenzoxazole (PBO), or any other suitable polymer-based dielectric material. In some embodiments, the redistribution layers 12a may include conductive materials. The conductive materials may include metal such as copper, aluminum, nickel, titanium, a combination thereof or other suitable metals.

The redistribution layers 12a may include metallic connection structures, i.e., metallic structures that provide electrical connection between nodes in the structure. The redistribution layers 12a may include a metallic seed layer and a metallic fill material on the metallic seed layer. The metallic seed layer may include, for example, a stack of a titanium barrier layer and a copper seed layer. The titanium barrier layer may have thickness in a range from 50 nm to 500 nm, and the copper seed layer may have a thickness in a range from 50 nm to 500 nm. The metallic fill material for the redistribution layers 12a may include copper, nickel, or copper and nickel. Other suitable metallic fill materials are within the contemplated scope of disclosure. The thickness of the metallic fill material that is deposited for each redistribution layer 12a may be in a range from 2 microns to 40 microns, such as from 4 microns to 10 microns, although lesser or greater thicknesses may also be used.

In at least one embodiment, the redistribution layers 12a may include a plurality of traces (lines) and a plurality of vias connecting the plurality traces to each other. The traces may be respectively located on the polymer layers 12 and may extend in the x-direction (first horizontal direction) and y-direction (second horizontal direction) on an upper surface of the polymer layers 12.

An upper passivation layer 13 may be formed on the chip-side surface of the interposer 10. The upper passivation layer 13 may include silicon oxide, silicon nitride, low-k dielectric materials such as carbon-doped oxides, extremely low-k dielectric materials such as porous carbon doped silicon dioxide, a combination thereof or other suitable material.

One or more upper bonding pads 13a may be formed in the upper passivation layer 13 on the chip-side surface of interposer 10. The upper passivation layer 13 may at least partially cover the upper bonding pads 13a. That is, the upper bonding pads 13a may be at least partially exposed on the chip-side surface of the interposer 10. The upper bonding pads 13a may be connected to the redistribution layers 12a. The upper bonding pads 13a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A lower passivation layer 14 may be formed on the board-side surface of the interposer 10. The lower passivation layer 14 may also include silicon oxide, silicon nitride, low-k dielectric materials such as carbon-doped oxides, extremely low-k dielectric materials such as porous carbon doped silicon dioxide, a combination thereof or other suitable material. The lower bonding pads 14a may be bonded to and electrically connected to the redistribution layers 12a. The lower bonding pads 14a may be located in the lower passivation layer 14. The lower passivation layer 14 may at least partially cover the lower bonding pads 14a. That is, the lower bonding pads 14a may be at least partially exposed on the board-side surface of the interposer 10. The lower bonding pads 14a may also include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The semiconductor dies (collectively referred to as semiconductor dies 140) may be attached to an upper surface of the interposer 10. The plurality of semiconductor dies 140 may include a first semiconductor die 141, second semiconductor die 142, third semiconductor die 143, fourth semiconductor die 144 and fifth semiconductor die 145 (see FIG. 1B). Although the package module 120 is illustrated as including a particular number of the semiconductor dies 140 of particular sizes having a particular arrangement, the number of semiconductor dies 140, the sizes of the semiconductor dies 140 and the arrangement of the semiconductor dies 140 is not limited to any particular number, size and arrangement. In particular, the package module 120 may include any number, size and arrangement of the semiconductor dies 140.

Generally, a thickness in the z-direction of each of the semiconductor dies 140 may be substantially the same. Thus, the upper surfaces of each of the first semiconductor die 141 and second semiconductor die 142 may be substantially coplanar (e.g., formed in the same x-y plane), and referred to collectively as the semiconductor die upper surface 140a.

The semiconductor dies 140 may be attached to (e.g., bonded to) the upper bonding pads 13a on the chip-side surface of the interposer 10 by microbumps 128. The microbumps 128 may each include a copper post and a solder bump on the copper post. A package module underfill layer 129 may be formed (e.g., individually or collectively) under and around each of the semiconductor dies 140. The package module underfill layer 129 may also be formed around the microbumps 128. The package module underfill layer 129 may thereby fix each of the semiconductor dies 140 to the interposer 10. The package module underfill layer 129 may be formed of an epoxy-based polymeric material. As noted above, in some embodiments in which the interposer 10 is omitted, the semiconductor dies 140 may be attached directly to the package substrate 110, by for example, the C4 bumps 121.

Each of the semiconductor dies 140 may include, for example, a singular semiconductor die structure, a system on chip (SOC) die, or a system on integrated chips (SoIC) die, and may be implemented by a three-dimensional integrated packaging technology (e.g., fan-out technology). In particular, each of the semiconductor dies 140 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., high-bandwidth memory (HBM) die, hybrid memory cube (HMC), dynamic random access memory (DRAM) die, a Wide I/O die, a M-RAM die, a R-RAM die, a NAND die, static random access memory (SRAM), etc.), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, an IPD die, a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc. Other dies are within the contemplated scope of this disclosure. In at least one embodiment, the first semiconductor die 141 may include a primary die (e.g., SOC die), and the second semiconductor die 142, third semiconductor die 143, fourth semiconductor die 144 and fifth semiconductor die 145 may include an ancillary die (e.g, memory/SOC die, HBM die, etc.).

The package module 120 may also include an upper molding layer 127 formed around the semiconductor dies 140. The upper molding layer 127 may have an outer sidewall that is substantially aligned with the outer sidewall of the interposer 10. The upper molding layer 127 may also have an upper surface that is substantially uniform (e.g., flat) and substantially coplanar with the upper surface 140a of the semiconductor dies 140. The upper molding layer 127 may be formed on outer sidewalls of each of the semiconductor dies 140. The upper molding layer 127 may be bonded to the outer sidewalls of each of the semiconductor dies 140.

The upper molding layer 127 may also be formed on and around the package module underfill layer 129. Although it is not illustrated in FIG. 1A, a height of an upper surface of the package module underfill layer 129 may less than a height of the semiconductor dies 140. In that case, the upper molding layer 127 may also be formed in a die-to-die gap between the semiconductor dies 140 and bonded to the inner sidewalls of the semiconductor dies 140. The upper molding layer 127 may also be formed on the package module underfill layer 129 in the die-to-die gap. The upper molding layer 127 may be bonded to the chip-side surface of the interposer 10 (e.g., the upper passivation layer 13) and the package module underfill layer 129.

In at least one embodiment, the upper molding layer 127 may be formed of a curable material that may cure to form a hard, solid structure. The upper molding layer 127 may include, for example, epoxy molding compound (EMC). In at least one embodiment, the upper molding layer 127 may include a material that is substantially similar to the package underfill layer 119 and package module underfill layer 129. In at least one embodiment, the upper molding layer 127 may include a polymeric material and in particular, an epoxy-based polymeric material. Other suitable molding materials may be used.

In at least one embodiment, the upper molding layer 127 may have a coefficient of thermal expansion (CTE) that is substantially similar to a CTE of the interposer 10. In at least one embodiment, the upper molding layer 127 may include an added material (e.g., filler material added to a polymeric material) for improving a property of the upper molding layer 127 (e.g., thermal conductivity, CTE, etc.). The added material may include, for example, metal powder, metal oxide powder, etc. Other materials in the upper molding layer 127 are within the contemplated scope of the disclosure.

The package structure 100 may further include a thermal interface material (TIM) layer 170 on the package module 120. The TIM layer 170 may be located on the upper surface of the upper molding layer 127 and on the upper surface 140a of the semiconductor dies 140. Although it is not shown in FIG. 1A, the TIM layer 170 may be formed on an upper surface of the package module underfill layer 129 in a die-to-die gap between the semiconductor dies 140.

The TIM layer 170 may include, for example, a grease type TIM, a paste type TIM, film type TIM, a gel type TIM, graphite film TIM, a liquid metal TIM (e.g., a gallium-rich TIM), a PCM type TIM, etc. In at least one embodiment, the TIM layer 170 may include a low-melting-temperature (LMT) metal TIM. The PCM type TIM may include, for example, a polymer-based PCM TIM. The PCM type TIM may improve void and delamination issues, enhance thermal contact resistance and improve thermal performance in a package structure 100. In at least one embodiment, the PCM type TIM may change its phase from solid to high viscosity semi liquid around 60° C. In at least one embodiment, the TIM layer 170 may include a gallium base, indium base, silver base, solder base, etc. Other types TIMs in the TIM layer 170 are within the contemplated scope of this disclosure.

The TIM layer 170 may be formed on the package module 120 to dissipate heat generated during operation of the package structure 100 (e.g., operation of the semiconductor dies 140). The TIM layer 170 may be attached to the package module 120, for example, by a thermally conductive adhesive. The TIM layer 170 may have a low bulk thermal impedance and high thermal conductivity. The bond-line-thickness (BLT) (e.g., a distance between the package lid 130 and the package module 120) may be less than about 100 μm, although greater or lesser distances may be used.

The package lid 130 may be located over the package module 120 and connected to the package substrate 110. The package lid 130 may include a package lid plate portion 130p formed on the TIM layer 170 over the package module 120. The package lid 130 may also include a package lid foot portion 130a located around an outer periphery of the package lid plate portion 130p. The package lid foot portion 130a may be fixed to the package substrate 110 by an adhesive layer 160.

The package lid plate portion 130p may include an outer package lid plate portion 130p-1 connected to the package lid foot portion 130a. The package lid plate portion 130p may also include an inner package lid plate portion 130p-2 over the package module 120. The package lid plate portion 130p may also include an underside 135 including a patterned bottom surface 131. The patterned bottom surface 131 may be located in the inner package lid plate portion 130p-2, but is not necessarily limited to the inner package lid plate portion 130p-2. The patterned bottom surface 131 may contact an upper surface of the TIM layer 170. The patterned bottom surface 131 may include recessed portions 131a and the TIM layer 170 may be formed or fill in the recessed portions 131a of the patterned bottom surface 131. In at least one embodiment, a portion of the TIM layer 170 (e.g., at least a portion of the TIM layer 170) may be located in the recessed portions 131a. In at least one embodiment, the TIM layer 170 may substantially fill the recessed portions 131a of the patterned bottom surface 131.

In one or more embodiments, the underside 135 including the patterned bottom surface 131 of the package lid plate portion 130p may directly contact an entire upper surface of the TIM layer 170. The TIM layer 170 may be compressed between the underside 135 of the package lid plate portion 130p and the package module 120. In particular, the TIM layer 170 may be compressed between the patterned bottom surface 131 and the upper surface of the upper molding layer 127 and between the patterned bottom surface 131 and the upper surface 140a of the semiconductor dies 140.

The package lid 130 may be formed, for example, of metal, ceramic or polymer material. In at least one embodiment, a material of the package lid 130 may include copper with a nickel coating surface. The nickel coating surface may have a thickness in a range of 1 μm to 10 μm. The package lid plate portion 130p may have a plate shape (e.g., planar shape) and be substantially parallel to an upper surface of the package substrate 110. The package lid plate portion 130p may extend, for example, in an x-y plane in FIG. 1A. The package lid plate portion 130p may include an outer sidewall that is substantially aligned with an outer sidewall of the package lid foot portion 130a. A center of inner package lid plate portion 130p-2 in the x-y plane may be substantially aligned in the z-direction with a center of the package module 120 in the x-y plane. An upper surface of the package lid plate portion 130p may be substantially parallel to the underside 135 of the package lid plate portion 130p.

The adhesive layer 160 may be formed on the package substrate 110 near the sidewall of the package module 120. The adhesive layer 160 may bond the package lid foot portion 130a to package substrate 110. A thickness of the adhesive layer 160 may be in a range from 50 μm to 200 μm. The adhesive layer 160 may include, for example, a silicone adhesive (e.g., containing aluminum oxide, zinc oxide, resin, etc.) or an epoxy adhesive. Other suitable adhesives may be used. The adhesive layer 160 may contact the backside metal layer or the recessed upper surface of the upper molding material layer.

One or more surface mount devices (SMDs) 180 may also be located under the package lid 130 on the chip-side surface of package substrate 110. The SMDs 180 may be located between the package lid foot portion 130a and the package module 120 on the package substrate 110. In at least one embodiment, the SMDs 180 may be located substantially equidistant (e.g., in the x-direction) between the package lid foot portion 130a and the interposer 10 of the package module 120. The SMDs 180 may be attached to the package substrate 110 by surface mount technology (SMT) and electrically connected to the metal interconnect structures 114b in the package substrate upper dielectric layer 114. The SMDs 180 may, therefore, be electrically coupled to the semiconductor dies 140 through the package substrate 110 and the interposer 10.

The SMDs 180 may include, for example, integrated circuits, passive components such as resistors, capacitors and inductors, active components such as two-terminal devices, diodes and three-terminal devices, and electromechanical devices such as switches/relays, connectors and micro-motors. In at least one embodiment the SMDs 180 may include transistors (e.g., metal oxide semiconductor field effect transistors (MOSFETs)), rectifiers and voltage regulators for power management applications.

Referring again to FIG. 1B, the package lid plate portion 130p has been omitted from FIG. 1B for ease of understanding. As illustrated in FIG. 1B, the package substrate 110 may have a rectangular shape in the plan view. A center of the package module 120 in the x-direction and y-direction may be substantially aligned with a center of the package substrate 110 in the x-direction and y-direction. The package substrate 110 may include a long side substantially parallel to a long side of the package module 120 and a short side substantially parallel to the short side of the package module 120.

The package lid foot portion 130a may also include a long side substantially parallel to the long side of the package module 120 and a short side substantially parallel to the short side of the package module 120. The package lid foot portion 130a may be attached continuously to the package substrate 110 around an entire periphery of the package module 120. A distance DO between the package lid foot portion 130a and the outer periphery (e.g. outer edge) of the package substrate 110 may be substantially uniform around the periphery of the package lid foot portion 130a. In at least one embodiment, a distance D1 between the upper molding layer 127 of the package module 120 and the package lid foot portion 130a may be substantially uniform around the entire periphery of the package module 120. In at least one embodiment, a distance D2 between the SMD 180 and the package module 120 may be substantially the same as a distance D3 between the SMD 180 and the package lid foot portion 130a.

Referring again to FIG. 1C, an interface between the outer package lid plate portion 130p-1 and the inner package lid plate portion 130p-2, may be substantially aligned with an outer sidewall 127a of the upper molding layer 127 of the package module 120. The plurality of recessed portions 131a may include an outermost recessed portion 131ao located over the package module 120. A distance D4 between the outer sidewall 127a of the upper molding layer 127 and the outermost recessed portion 131ao of the patterned bottom surface 131 may be in a range from 0.5 mm to 1.0 mm. In at least one embodiment, the underside 135 may have a substantially uniform (e.g., flat) bottom surface in the outer package lid plate portion 130p-1. The package lid plate portion 130p may have a thickness T₁₃₀ₚ outside of the recessed portions 131a in a range from 0.5 mm to 3.0 mm.

The TIM layer 170 may have a first thickness T1 (in the z-direction) within the plurality of recessed portions 131a. The first thickness T1 may be in a range from 100 μm to 1000 μm. The TIM layer 170 may also include a second thickness T2 less than the first thickness T1 outside the plurality of recessed portions 131a. The second thickness T2 may be in a range from 50 μm to 500 μm.

The recessed portions 131a may have a depth D5 (in the z-direction) in a range 50 μm to 500 μm. A sidewall of the recessed portions 131a may extend in the z-direction substantially perpendicular to an upper surface of the package lid plate portion 130p. A ratio of the depth D5 of the recessed portions 131a to the first thickness T1 of the TIM layer 170 may be in a range from 0.2 to 0.8. A width W of the recessed portions 131a may be in a range from 100 μm to 1000 μm. As illustrated in FIG. 1C, the plurality of recessed portions 131a may be substantially filled by the TIM layer 170. However, in at least one embodiment, one or more of the recessed portions 131a may be less than substantially filled (e.g., only partially filled) by the TIM layer 170. In at least one embodiment, one or more recessed portions 131a (e.g., each of the recessed portions 131a) may be 85% to 95% filled by the TIM layer 170.

The depth D5, width W, and number of recessed portions 131a in the patterned bottom surface 131 of the package lid plate portion 130p may depend upon the type of TIM layer 170 being used. For example, the patterned bottom surface 131 may include a higher number of recessed portions 131a having a greater depth D5 and greater width W for a TIM layer 170 having a higher CTE, whereas the patterned bottom surface 131 may include a lower number of recessed portions 131a having a lesser depth D5 and lesser width W for a TIM layer 170 having a lower CTE. As another example, the patterned bottom surface 131 may include a higher number of recessed portions 131a having a greater depth D5 and greater width W for a TIM layer 170 have a lower thermal conductivity, whereas the patterned bottom surface 131 may include a lower number of recessed portions 131a having a lesser depth D5 and lesser width W for a TIM layer 170 have a higher thermal conductivity.

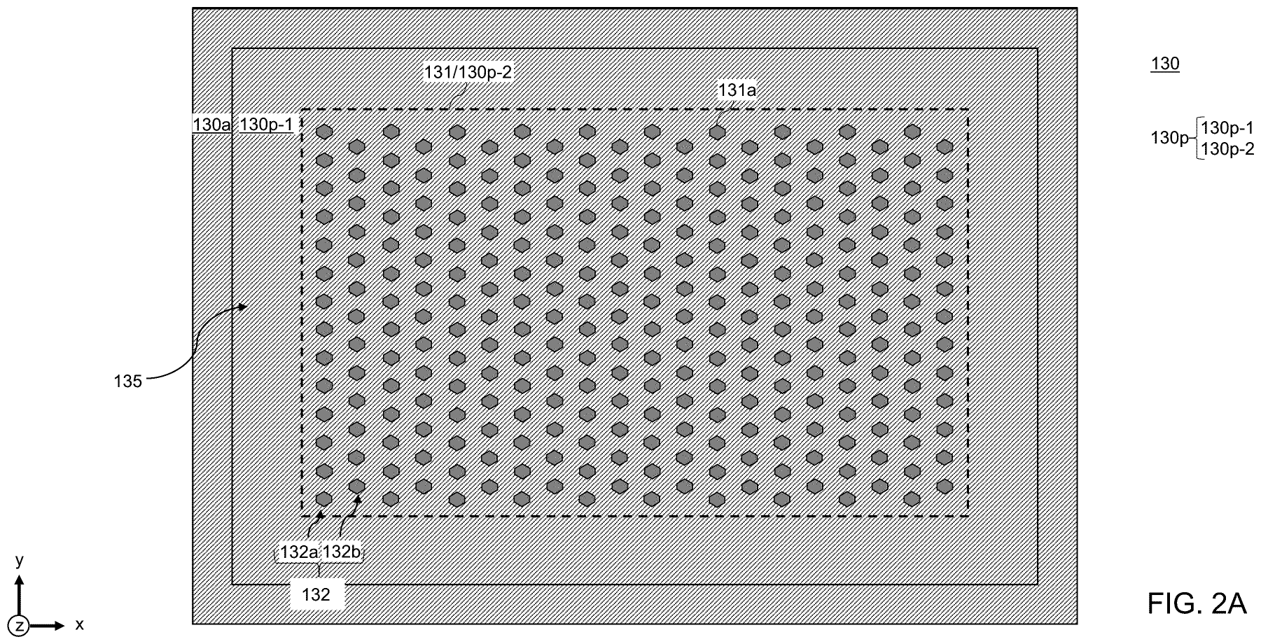

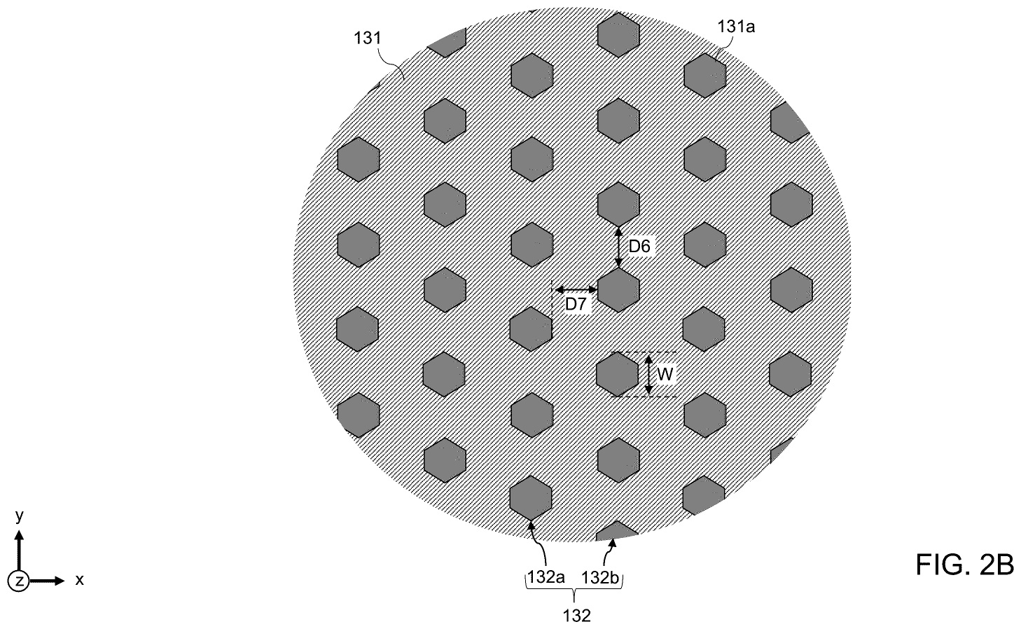

FIG. 2A is a plan view (e.g., top-down view) of the underside 135 of the package lid plate portion 130p, according to one or more embodiments. As illustrated in FIG. 2A, an outer perimeter of the patterned bottom surface 131 may substantially correspond to an outer perimeter of the inner package lid plate portion 130p-2. The patterned bottom surface 131 may have an outer shape that substantially corresponds to an outer shape of the package lid 130 and to an outer shape of the package lid place portion 130p. The outer shape of the patterned bottom surface 131 may include a rectangular shape, square shape, etc. A center of the patterned bottom surface 131 may be substantially aligned with a center of the package lid plate portion 130p.

The recessed portions 131a may be uniformly arranged in patterned bottom surface 131. A concentration of the recessed portions 131a may be substantially uniform over the entirety of the patterned bottom surface 131. The recessed portions 131a may be formed in a plurality of columns 132 that form an array of the recessed portions 131a. The plurality of columns 132 may each extend lengthwise in the y-direction. In at least one embodiment, the array may include a staggered array and the columns 132 may include first columns 132a and second columns 132b which are staggered (e.g., offset) from the first columns 132a in the y-direction. The first columns 132a and second columns 132b may be alternatingly formed in the x-direction across the patterned bottom surface 131.

An outer shape of each of the recessed portions 131a may include, for example, one or more of a hexagon shape, a round shape, and oval shape, a capsule shape, a ladder shape, a square shape, a rectangular shape, a triangular shape, a trapezoid shape and a diamond shape. Other suitable shapes may be used. Although FIG. 2A illustrates the recessed portions 131a having the same shape (e.g., hexagonal), the recessed portions 131a may have different shapes. In at least one embodiment, a shape of the recessed portions 131a may be determined based on an expected thermal performance of the package module 120. For example, the recessed portions 131a in a location of the patterned bottom surface 131 corresponding to a hot spot of the package module 120 may have a first shape (e.g., hexagonal shape), whereas the recessed portions 131a in a location of the patterned bottom surface 131 not corresponding to a hot spot of the package module 120 may have a second shape (e.g., circular shape).

In at least one embodiment, the patterned bottom surface 131 may having a honeycomb design. A surface with a honeycomb design typically consists of a regular pattern of recessed portions 131a (e.g., cells). The recessed portions 131a may have a hexagonal shape, but other suitable shapes may be used. The walls between the recessed portions 131a may be substantially uniform. The honeycomb design may be is highly symmetrical and highly regular, with a substantially constant distance between the walls of adjacent recessed portions. The honeycomb design may also have a large surface area-to-volume ratio which may allow for efficient heat transfer and fluid flow (e.g., flow of TIM layer 170) into the recessed portions 131a.

FIG. 2B is a detailed plan view (e.g., top-down view) of the patterned bottom surface 131, according to one or more embodiments. The recessed portions 131a may have substantially the same width W in both the x-direction and the y-direction. In at least one embodiment, the recessed portions 131a may have width W that is different in the x-direction than in the y-direction (or off-axis when measured point to point, for example, in the embodiment in which the recessed portion shape is hexagonal, the width may not always be parallel with the x and y directions). The width W of the recessed portions 131a in both the x-direction than the y-direction may be in a range from 100 μm to 1000 μm (e.g., about 300 μm).

In addition, the recessed portions 131a within a column 132a, 132b of the plurality of columns 132 may be separated by a distance D6 (e.g., row pitch distance) in the y-direction in a range from 100 μm to 1000 μm (e.g., about 260 μm). The columns 132a, 132b of the plurality of columns 132 may be separated by a distance D7 in the x-direction in a range from 100 μm to 1000 μm (e.g., about 300 μm) (e.g., column pitch distance).

In at least one embodiment, the width W in the y-direction may be substantially the same as the distance D7 between column 132a and column 132b. In at least one embodiment, the distance D6 between the recessed portions 131a in a column 132 may be less than the width W in the y-direction. In at least one embodiment, the distance D6 between the recessed portions 131a in a column 132 may be less than the distance D7 between column 132a and column 132b. In at least one embodiment, the distance D6 between the recessed portions 131a in column 132a may be different than the distance D6 between the recessed portions 131a in column 132b.

The patterned bottom surface 131 of the package lid plate portion 130p may inhibit pump-out of the TIM layer 170. The TIM layer 170 (e.g., PCM type TIM layer) may provide a good heat dissipation performance, and the patterned bottom surface 131 may help inhibit pump-out at a hot spot of one or more semiconductor dies 140 in the package module 120 of the package structure 100. The patterned bottom surface 131 may increase a contact area between the package lid plate portion 130p and the TIM layer 170 and enhance an interfacial thermal conductance. The patterned bottom surface 131 may also provide extra spacing between the package lid plate portion 130p and the package module 120 which may help to inhibit the TIM layer 170 from bleeding out of the space. Further, in the case where the package structure 100 includes the SMDs 180 on the package substrate 110 adjacent the package module 120, the patterned bottom surface 131 may help to inhibit the TIM layer 170 from pumping out (sometimes referred to as bleeding out) and making contact with the SMDs 180. Such pump-out may cause an electrical failure in the package structure 100. The patterned bottom surface 131 may, therefore, reduce a risk of pump-out which may lead to increased thermal resistance and temperature rise, improve heat dissipation by increasing a contact area of the package lid plate portion 130p, and provide extra spacing to prevent bleeding of the TIM layer 170.

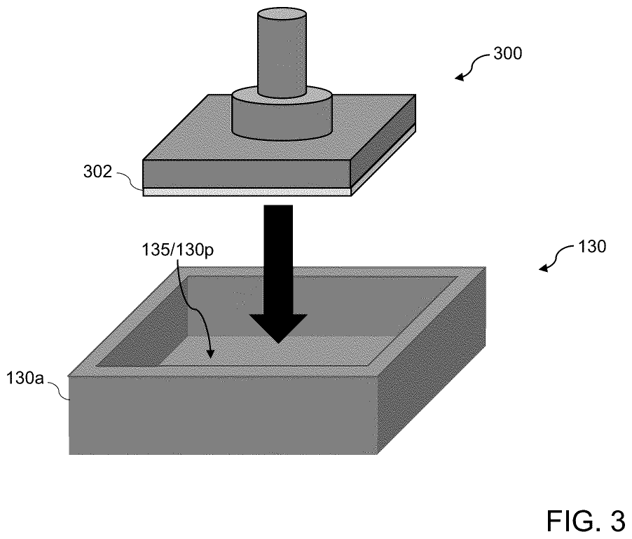

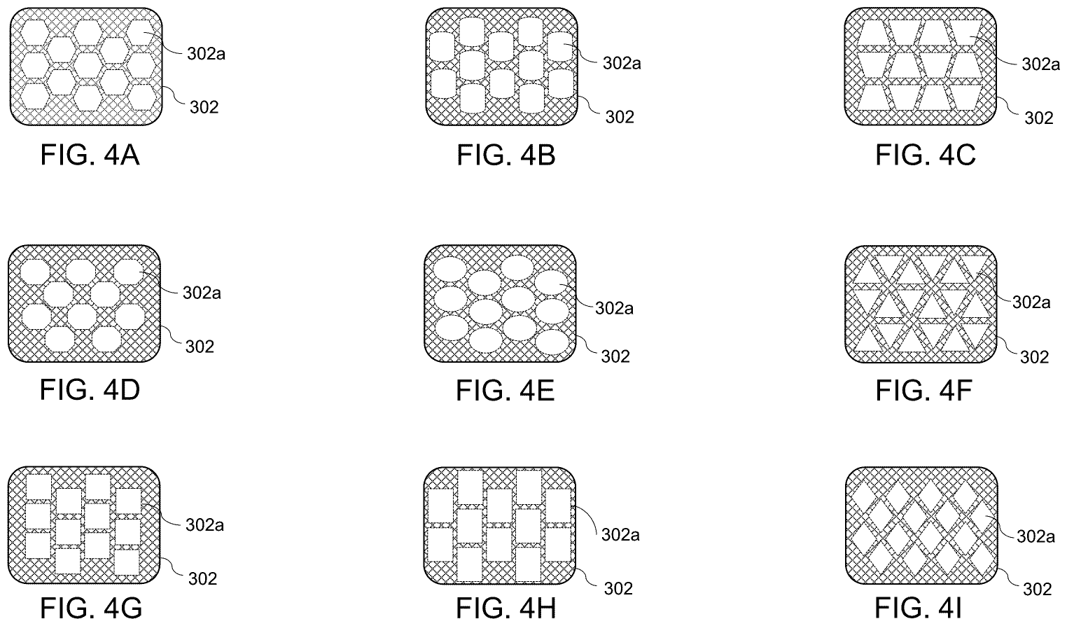

FIG. 3 illustrates a stamping process of forming the patterned bottom surface 131 of the package lid 130 according to one or more embodiments. FIGS. 4A-4I illustrates various protrusion pads 302 that may be used in the stamping process according to one or more embodiments.

After the package lid 130 is formed, for example, by milling using a computer numerical control (CNC) milling machine, or by molding or stamping, the patterned bottom surface 131 may be formed on the underside 135 of the package lid plate portion 130p. FIG. 3 illustrates forming the patterned bottom surface 131 by a stamping process. However, the patterned bottom surface 131 may be formed by other suitable methods such as an etching process. In the etching process, for example, a patterned photoresist mask may be formed on the underside 135 of the package lid plate portion 130p. The photoresist mask may include openings having a location and shape corresponding to a location and shape of the recessed portions 131a (see FIG. 2A) in the patterned bottom surface 131. An etching process may then be performed through openings in the photoresist mask in order to form the recessed portions 131a of the patterned bottom surface 131.

As illustrated in FIG. 3, a stamp 300 used in the stamping process may include a protrusion pad 302 formed on a bottom of the stamp 300. The protrusion pad 302 may include a plurality of protrusions 302a (see FIGS. 4A-4I) that may transfer a pattern onto the underside 135 of the package lid plate portion 130p. In the stamping process, the package lid 130 may be inverted and placed on a rigid structure having a flat surface such as a table-top. The stamp 300 may then be located over the underside 135 of the package lid plate portion 130p, and lowered into the package lid 130 so that the protrusion pad 302 contacts the underside 135 of the package lid plate portion 130p. The stamp 300 may then be forced downwardly with a pressing force so that the protrusions 302a are pressed into the underside 135 of the package lid plate portion 130p. The pressing force may be applied with sufficient magnitude and duration so as to imprint the shape of the protrusions 302a in the protrusion pad 302 in a surface of the underside 135 and thereby form the patterned bottom surface 131. The depth of the recessed portions 131a may be proportional to the magnitude and duration of the applied pressing force.

As illustrated in FIGS. 4A-4I, the protrusion pad 302 may include hexagonal-shaped protrusions 302a (FIG. 4A), rounded rectangular-shaped protrusions 302a (FIG. 4B), trapezoid-shaped protrusions 302a (FIG. 4C), octagonal-shaped protrusions 302a (FIG. 4D), oval-shaped protrusions 302a (FIG. 4E), triangular-shaped protrusions 302a (FIG. 4F), square-shaped protrusions 302a (FIG. 4G), rectangular-shaped protrusions 302a (FIG. 4H), and diamond-shaped protrusions 302a (FIG. 4I). Other shapes of the protrusions 302a are within the contemplated scope of disclosure. In some embodiments, the shape of the protrusions (and thus, the resulting recessed portions 131a) may be substantially uniform. In some embodiments, the shape of the protrusions (and thus, the resulting recessed portions 131a) may vary. In at least one embodiment, the protrusion pad 302 may be removably fixed to the bottom of the stamp 300 to allow the convenient replacement of the protrusion pad 302 with a protrusion pad 302 having a different design.

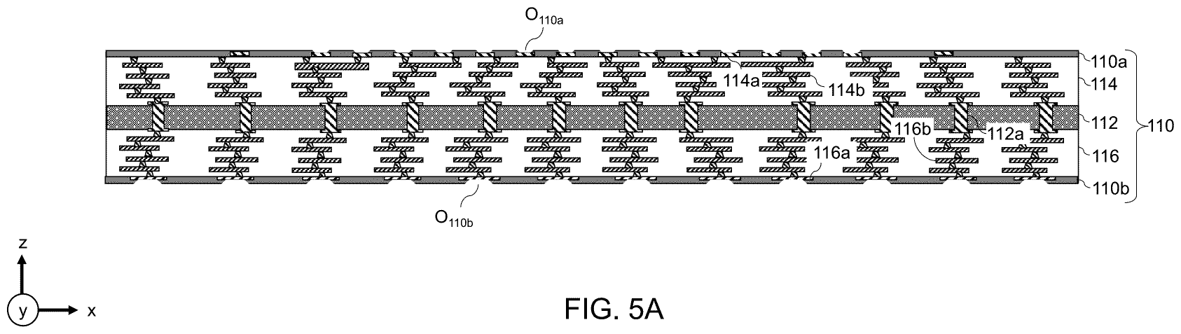

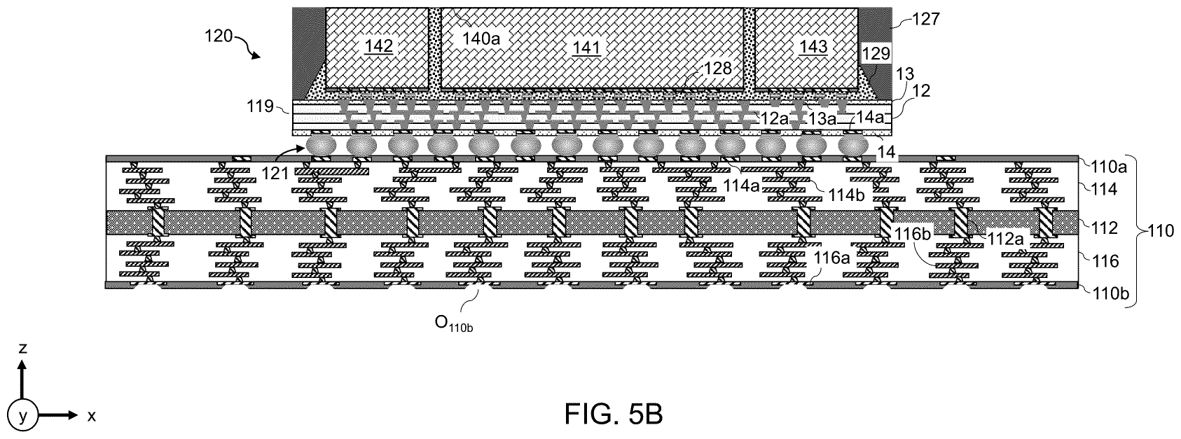

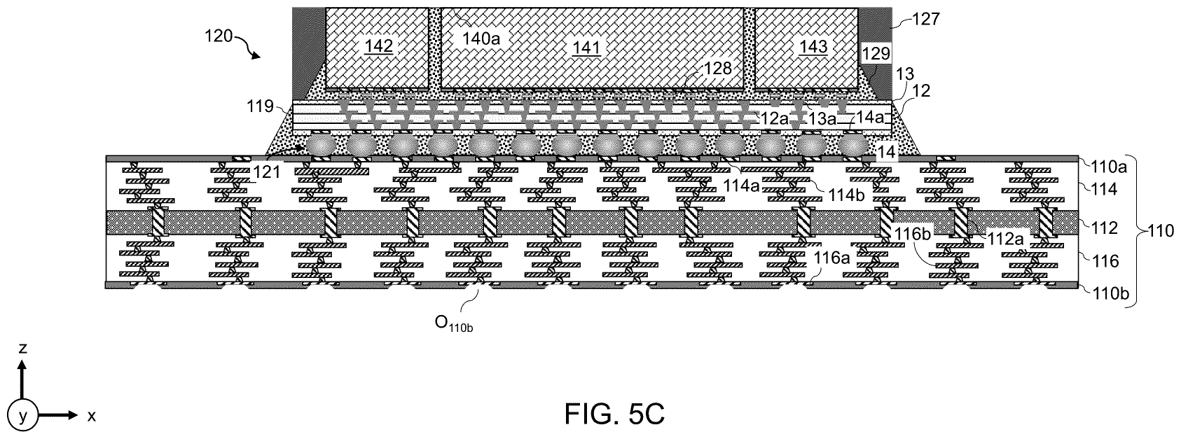

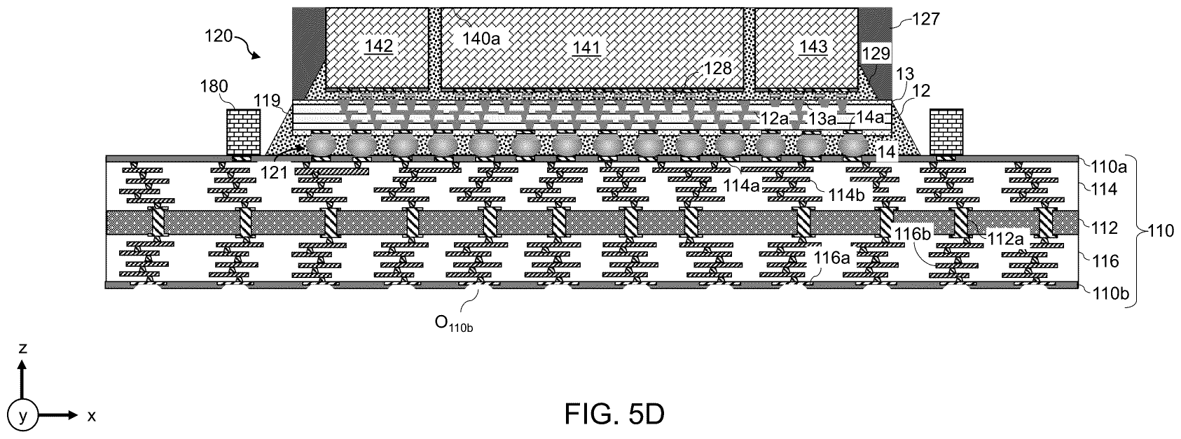

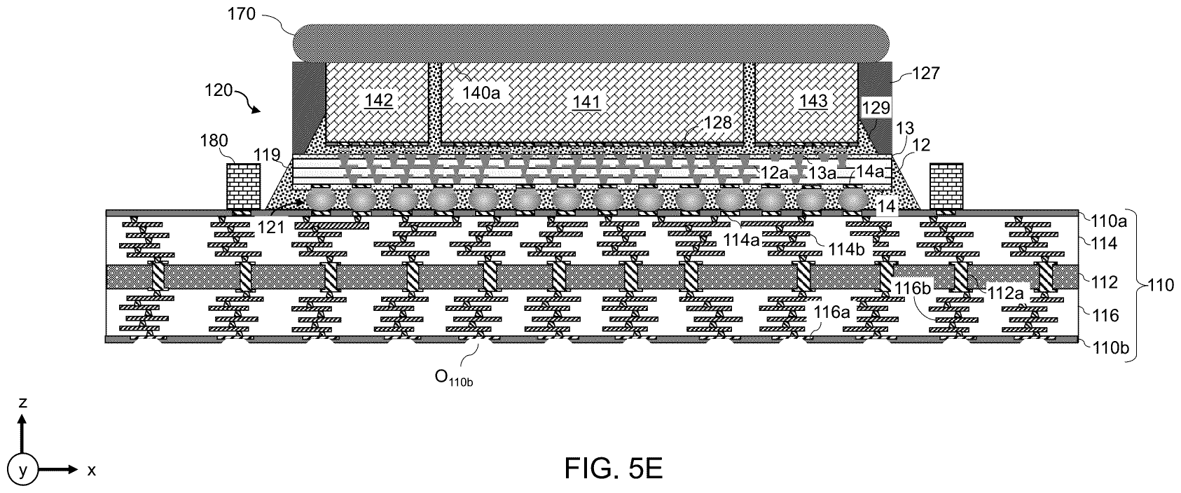

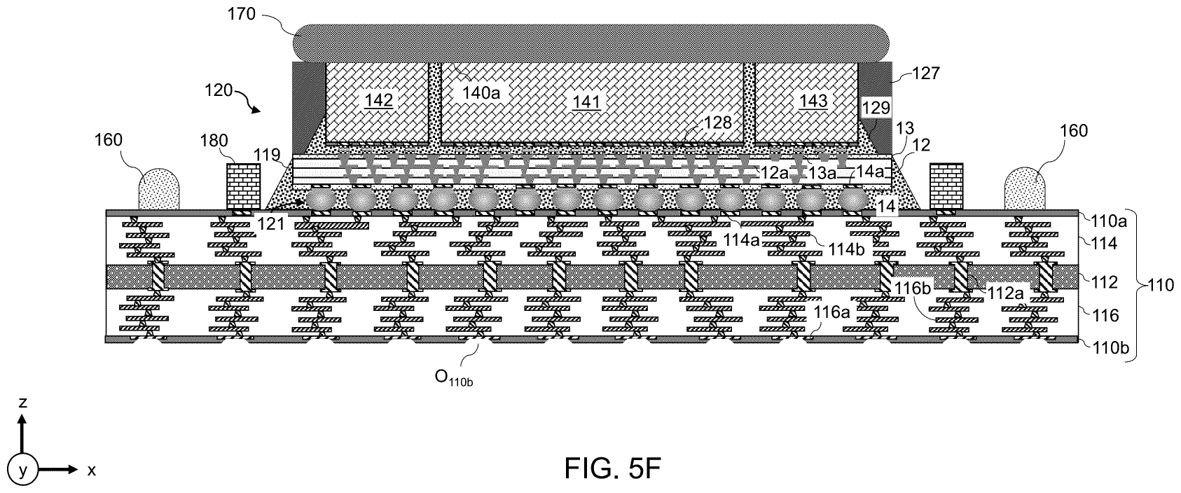

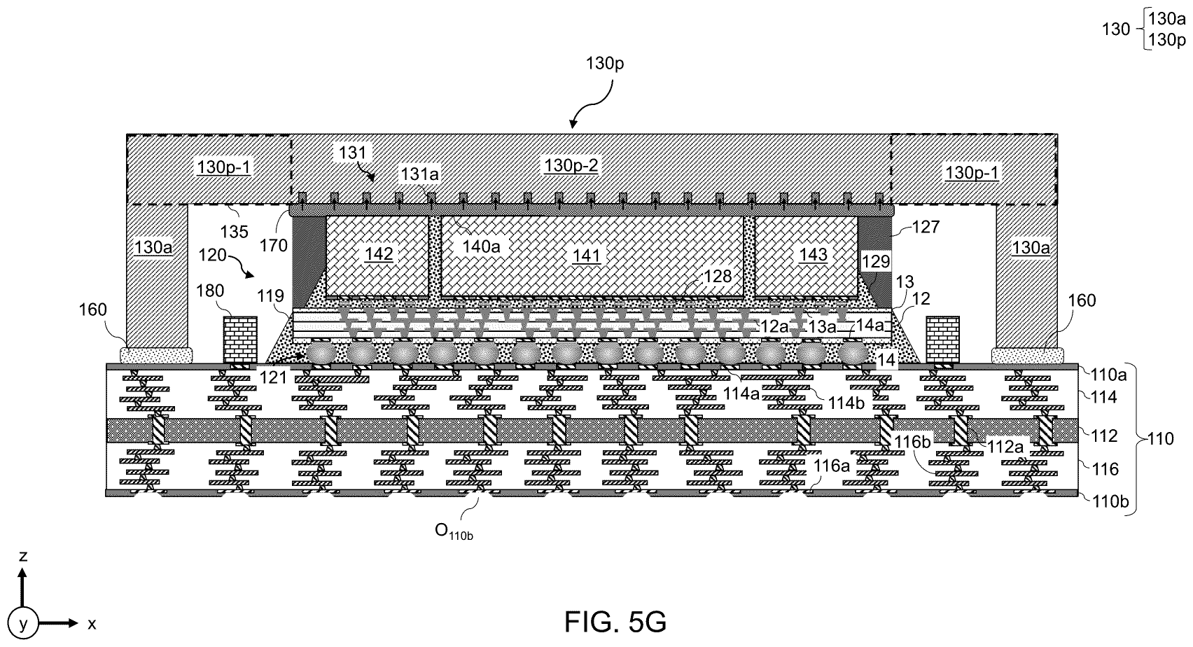

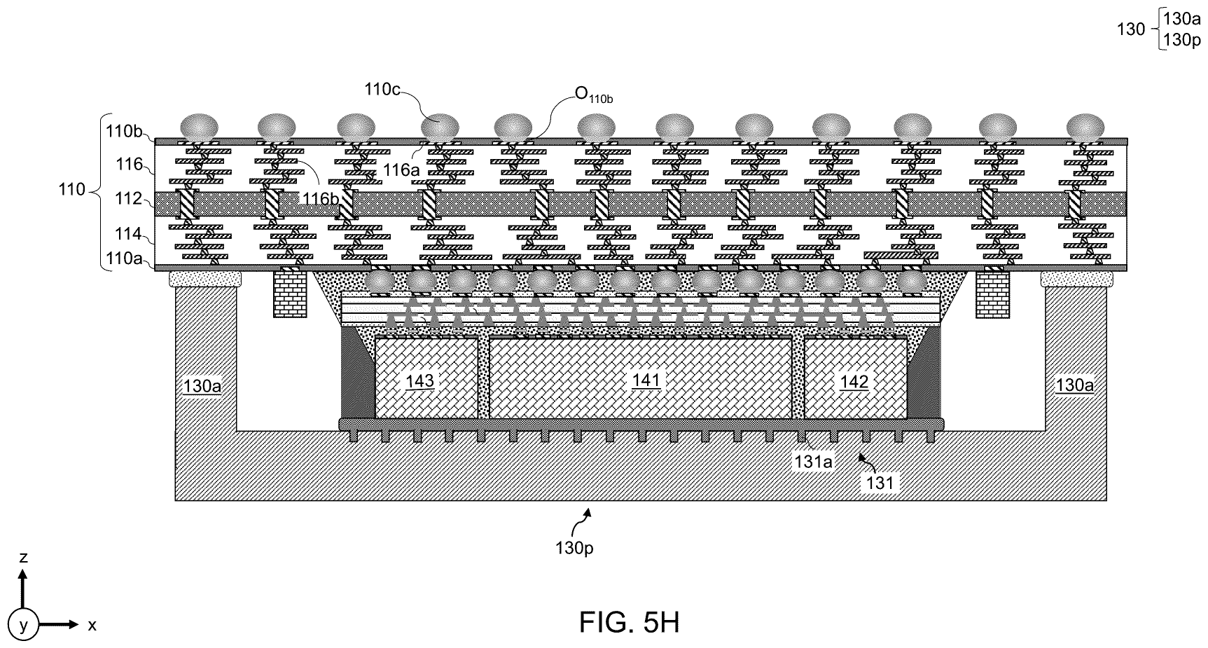

FIGS. 5A-5H illustrate various intermediate structures in a method of forming the package structure 100 according to one or more embodiments. FIG. 5A is a vertical cross-sectional view of an intermediate structure including the package substrate 110 having package substrate upper bonding pads 114a and package substrate lower bonding pads 116a, according to one or more embodiments. The package substrate 110 including the core 112, the package substrate upper dielectric layer 114, and the package substrate lower dielectric layer 116 may be provided.

The package substrate upper bonding pads 114a may be formed, for example, on an uppermost dielectric layer of the package substrate upper dielectric layer 114. The package substrate upper bonding pads 114a may be formed to contact the metal interconnect structures 114b. The package substrate upper bonding pads 114a may be formed by depositing a metal layer (e.g., copper, aluminum or other suitable conductive materials) on the upper surface of the package substrate upper dielectric layer 114. The metal layer may then be patterned by etching (e.g., by wet etching, dry etching, etc.) to form the package substrate upper bonding pads 114a. Other suitable metal layer materials and etching processes may be within the contemplated scope of disclosure.

The package substrate lower bonding pads 116a may be formed, for example, on a lowest dielectric layer of the package substrate lower dielectric layer 116. The package substrate lower bonding pads 116a may be formed to contact the metal interconnect structures 116b. The package substrate lower bonding pads 116a may be formed in a manner similar to the manner of forming the package substrate upper bonding pads 114a (e.g., depositing a metal layer, patterning the metal layer by etching, etc.).

After formation, the package substrate upper bonding pads 114a and package substrate lower bonding pads 116a may optionally undergo a surface roughening treatment (e.g., copper zarazara (CZ) treatment). In the surface roughening treatment, a surface of the package substrate upper bonding pads 114a (e.g., a copper surface) and surface of the package substrate lower bonding pads 116a (e.g., a copper surface) may be etched by an organic acid-type microetching solution, to create a super-roughened surface (e.g., copper surface). The uniquely-roughened copper surface topography of the package substrate upper bonding pads 114a and package substrate lower bonding pads 116a may help to achieve a high copper-to-resin adhesion.

The package substrate upper passivation layer 110a and package substrate lower passivation layer 110b may then be formed on the package substrate upper bonding pads 114a and package substrate lower bonding pads 116a, respectively. In at least one embodiment, the package substrate upper passivation layer 110a may include a solder resist layer (e.g., polymer material), also referred to as a solder mask. The package substrate upper passivation layer 110a may also be referred to as the upper solder resist layer 110a, and the package substrate lower passivation layer 110b may also be referred to as the lower solder resist layer 110b.

The package substrate upper passivation layer 110a and package substrate lower passivation layer 110b may be applied concurrently. The package substrate upper passivation layer 110a and package substrate lower passivation layer 110b may be applied, for example, as a liquid photo-imageable film. The liquid photo-imageable film can be applied, for example, by silk-screening or spraying the liquid photo-imageable film onto the surface of the package substrate 110. The liquid photo-imageable film may be applied over the package substrate upper bonding pads 114a and the package substrate lower bonding pads 116a. The package substrate upper passivation layer 110a and package substrate lower passivation layer 110b may alternatively be applied as a dry-film photo-imageable film that may be vacuum-laminated onto the surface of the package substrate 110 and over the package substrate upper bonding pads 114a and package substrate lower bonding pads 116a, respectively. The package substrate upper passivation layer 110a and package substrate lower passivation layer 110b may alternatively or additionally be formed, for example, by chemical vapor deposition (CVD), physical vapor deposition (PVD), spin coating, lamination or other suitable deposition technique.

The package substrate upper passivation layer 110a and package substrate lower passivation layer 110b may be applied to have a thickness that is slightly greater than a thickness of the package substrate upper bonding pads 114a and package substrate lower bonding pads 116a, respectively. Alternatively, the package substrate upper passivation layer 110a and package substrate lower passivation layer 110b may be applied so as to have an upper surface that is substantially coplanar with an upper surface of the package substrate upper bonding pads 114a and package substrate lower bonding pads 116a, respectively.

Openings O₁₁₀ₐ may then be formed in the package substrate upper passivation layer 110a so as to expose the upper surface of the package substrate upper bonding pads 114a. Openings O_{110b} may be formed in the package substrate lower passivation layer 110b to expose an upper surface of the package substrate lower bonding pads 116a. The openings O₁₁₀ₐ and the openings O_{110b} may be formed, for example, by using a photolithographic process. In at least one embodiment, the openings O₁₁₀ₐ and the openings O_{110b} may be formed in separate photolithographic processes.

The photolithographic process (e.g., processes) used to form the openings O110a may include forming a patterned photoresist mask (not shown) on the package substrate upper passivation layer 110a, and etching (e.g., wet etching, dry etching, etc.) the exposed upper surface of the package substrate upper passivation layer 110a through openings in the photoresist mask. The photoresist mask may be subsequently removed by ashing, dissolving the photoresist mask or by consuming the photoresist mask during the etch process.

The photolithographic process (e.g., processes) used to form the openings O110b may include forming a patterned photoresist mask (not shown) on the package substrate lower passivation layer 110b, and etching (e.g., wet etching, dry etching, etc.) the exposed upper surface of the package substrate lower passivation layer 110b through openings in the photoresist mask. The photoresist mask may be subsequently removed by ashing, dissolving the photoresist mask or by consuming the photoresist mask during the etch process.

After the openings O₁₁₀ₐ are formed in the package substrate upper passivation layer 110a and the openings O_{110b} are formed in the package substrate lower passivation layer 110b, the package substrate upper passivation layer 110a (upper solder resist layer) and the package substrate lower passivation layer 110b (lower solder resist layer) may be cured such as by a thermal cure or ultraviolet (UV) cure.

FIG. 5B illustrates a vertical cross-sectional view of an intermediate structure in which the package module 120 may be mounted on the package substrate 110, according to one or more embodiments. The package module 120 may be mounted on the package substrate 110, for example, by a flip chip bonding (FCB) process. The semiconductor die module 121 may be positioned over the package substrate 110, for example, by an electromechanical pick-and-place (PNP) machine. The C4 bumps 121 on the semiconductor die module 121 may then be lowered onto the package substrate upper bonding pads 114a of the package substrate 110 and heated in order to collapse the C4 bumps 121 and bond the C4 bumps 121 to the package substrate upper bonding pads 114a.

FIG. 5C illustrates a vertical cross-sectional view of an intermediate structure in which the package underfill layer 119 may be formed on the package substrate 110 according to one or more embodiments. The package underfill layer 119 may be formed of an epoxy-based polymeric material. As illustrated in FIG. 5C, the package underfill layer 119 may be formed (e.g., injected) under and around the package module 120 and the C4 bumps 121 to the package substrate 110. The package underfill layer 119 may then be cured, for example, in a box oven for duration in a range from 60 minutes to 120 minutes at a temperature in a range from 120° C. to 180° C. to provide the package underfill layer 119 with a sufficient stiffness and mechanical strength.

FIG. 5D illustrates a vertical cross-sectional view of an intermediate structure in which the SMDs 180 may be mounted on the package substrate 110, according to one or more embodiments. The SMDs 180 may then be positioned over the package substrate 110, for example, by an electromechanical pick-and-place (PNP) machine. The SMDs 180 (e.g., under the control of the PNP machine) may then be lowered onto the package substrate 110 and attached to package substrate 110 by adhesive (not shown). The adhesive may be substantially similar to the adhesive layer 160. The SMDs 180 may include bonding pads (not shown) that may be bonded to the package substrate upper bonding pads 114a of the package substrate 110.

FIG. 5E illustrates a vertical cross-sectional view of an intermediate structure in which the TIM layer 170 may be attached to (e.g., formed on) the package module 120 according to one or more embodiments. A thermally conductive adhesive may or may not be applied to the upper surface of the package module 120, depending upon the type of TIM layer 170 is being used. A material of the TIM layer 170 may be in the form of a grease, gel, paste, etc. in which case the material may be dispensed onto the thermally conductive adhesive if present or onto the upper surface of the package module. If the TIM layer 170 is a solid, the TIM layer 170 may then be pressed onto the package module 120 or onto the adhesive if present.

FIG. 5F illustrates a vertical cross-sectional view of an intermediate structure in which the adhesive layer 160 may be applied to the package substrate 110 according to one or more embodiments. The adhesive layer 160 may be dispensed onto the package substrate 110 with a dispensing tool (e.g., automated dispensing tool). The dispensing tool may dispense the adhesive layer 160 in a frame shape around the package module 120. At the time of application, the adhesive layer 160 may be sufficiently rigid so as to form a semi-solid bead on the surface of the package substrate 110. In at least one embodiment, a viscosity of each the adhesive layer 160 at the time of application may be 50,000 centipoise (cp) or greater. The shape of the semi-solid bead may remain substantially unchanged between the time of application by the dispensing tool and the later time of attaching the package lid 130. The location of the frame shape of the adhesive layer 160 may correspond to a location of the foot portion 130a of the package lid 130 (e.g., see FIG. 1B). A pressing of the package lid 130 onto the adhesive layer 160 may deform the adhesive layer 160.

FIG. 5G illustrates a vertical cross-sectional view of an intermediate structure in which the package lid 130 may be attached to (e.g., mounted on) the package substrate 110 according to one or more embodiments. After the patterned bottom surface 131 has been formed on the underside 135 of the package lid plate portion 130p (see FIGS. 3-4I), the package lid 130 may be attached to the package substrate 110. In at least one embodiment, the package substrate 110 with the package module 120 may be placed on a surface. The package lid 130 may then be positioned over the package substrate 110, for example, by an electromechanical pick-and-place (PNP) machine. The package lid 130 may then be lowered down over the package module 120 and onto the package substrate 110. The foot portion 130a of the package lid 130 may then be aligned with the adhesive layer 160 formed on the package substrate 110. The package lid 130 may then be pressed downward on to the TIM layer 170 by applying a pressing force down onto the package lid 130 so that the foot portion 130a of the package lid 130 may be attached to the package substrate 110 through the adhesive layer 160.

By pressing the package lid 130 onto the TIM layer 170, the TIM layer 170 may be forced to flow (shown by directional arrows) into the recessed portions 131a of the patterned bottom surface 131. The quantity (e.g., volume) of TIM layer 170 dispensed on the package module 120 may be sufficient to substantially fill the recessed portions 131a, while leaving adequate spacing between the package lid plate portion 130p and the package module 120.

The package lid 130 may then be clamped to the package substrate 110 for a period to allow the adhesive layer 160 to cure and form a secure bond between the package substrate 110 and the package lid 130. The clamping of the package lid 130 to the package substrate 110 may be performed, for example, by using a heat clamp module. The heat clamp module may apply a uniform force across the upper surface of the package lid 130. In one or more embodiments, the heat clamp module may apply the pressing force to the package lid 130.

FIG. 5H illustrates a vertical cross-sectional view of an intermediate structure in which a plurality of solder balls 110c may be formed on the package substrate 110 according to one or more embodiments. The plurality of solder balls 110c may be formed on the package substrate lower bonding pads 116a through the openings O110b in the package substrate lower passivation layer 110b. The solder balls 110c may be formed, for example, by an electroplating process. The solder balls 110c may be formed, for example, so as to be located under the foot portion 130a and under the package module 120 and therebetween. The plurality of solder balls 110c may constitute a ball-grid array (BGA) that may allow the package structure 100 to be securely mounted (e.g., by surface mount technology (SMT)) on a substrate such as a printed circuit board and electrically coupled to the substrate. Formation of the solder balls 110c may complete the formation of the package structure 100.

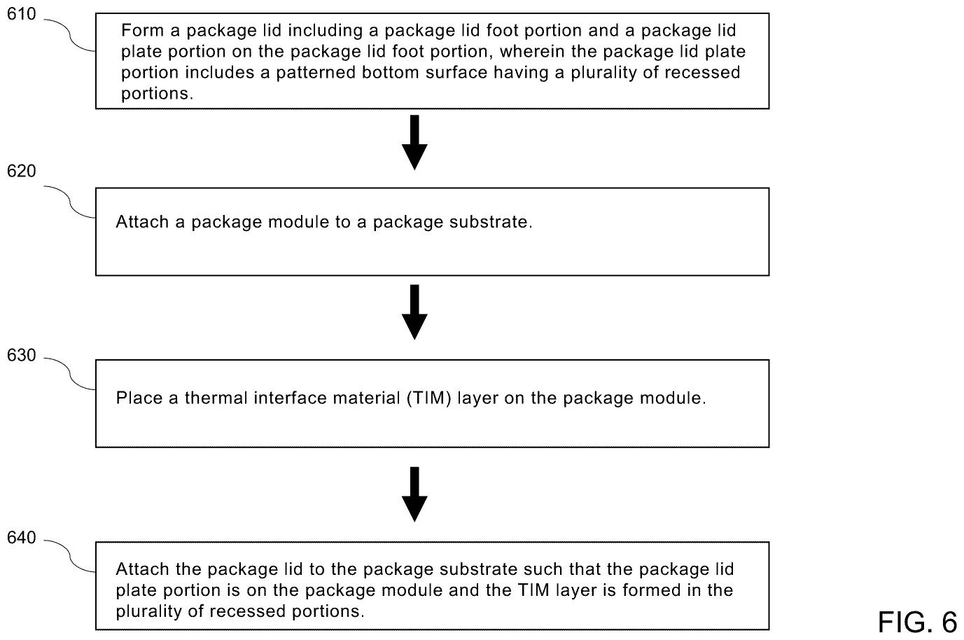

FIG. 6 is a flow chart illustrating a method of forming the package structure 100 according to one or more embodiments. Step 610 includes forming a package lid including a package lid foot portion and a package lid plate portion on the package lid foot portion, wherein the package lid plate portion includes a patterned bottom surface having a plurality of recessed portions. Step 620 includes attaching a package module to a package substrate. Step 630 includes placing a thermal interface material (TIM) layer on the package module. Step 640 includes attaching the package lid to the package substrate such that the package lid plate portion is on the package module and the TIM layer is formed in the plurality of recessed portions. The method illustrated in FIG. 6 is not intended to limit the method to a specific sequence of steps. For example, the formation of the package lid in step 610 may occur at any time prior to attaching the package lid 130 to the package substrate 110, but not necessarily prior to the attaching of the package module 120 to the package substrate 110 step 620 and/or the placement of TIM layer 170 to the package module 120.

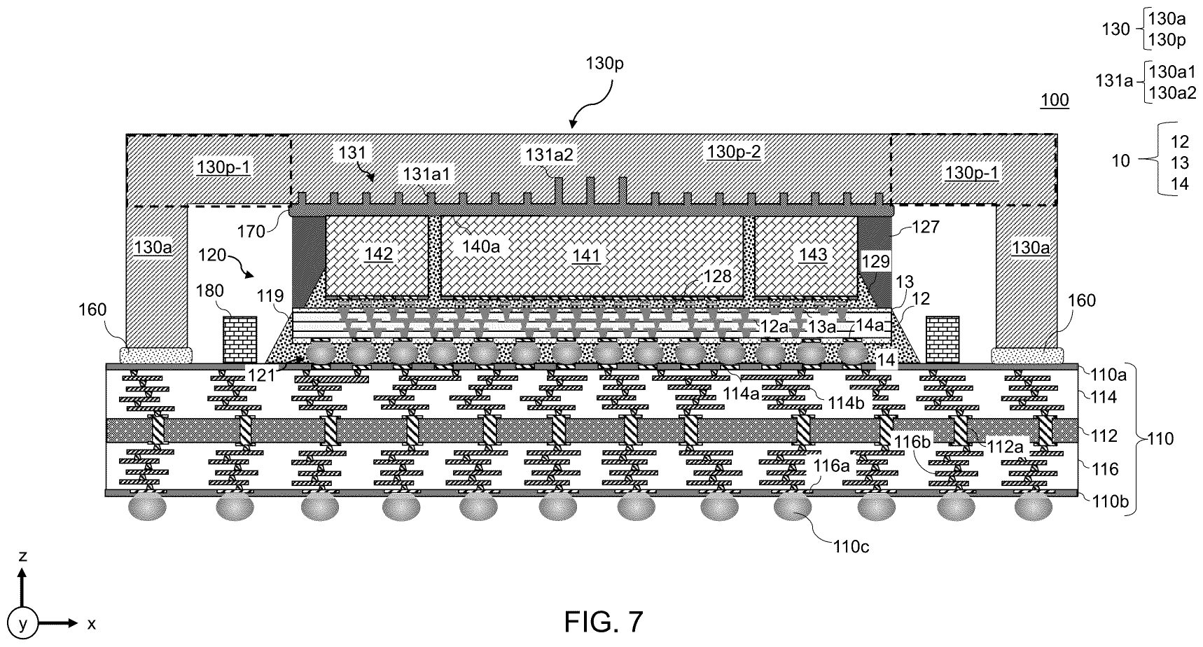

FIG. 7 is a vertical cross-sectional view of a package structure 100 having a first alternative design, according to one or more embodiments. As illustrated in FIG. 7, in the first alternative design, the recessed portions 131 may have a plurality of different depths. In particular, the recessed portions 131 may include first recessed portions 131a1 having a first depth and second recessed portions 131a2 having a second depth greater than the first depth. In at least one embodiment, the second depth may be in a range from 1.1 to 2.0 times the first depth.

The second recessed portions 131a2 may provide a greater contact area between the package lid plate portion 130p and the TIM layer 170. Therefore, the patterned bottom surface 131 may be designed so that the second recessed portions 131a2 are located on an area of the package module 120 generating more heat compared to other areas of the package module 120. While FIG. 7 illustrates the second recessed portions 131a2 having a greater depth formed in the center of the package lid 130, the second recessed portions 131a2 may be located in different positions on the package lid 130. For example, the second recessed portions 131a2 may be offset from the center of the package lid 130. Moreover, there may be multiple areas in which the second recessed portions 131a2 may be formed in the package lid 130.

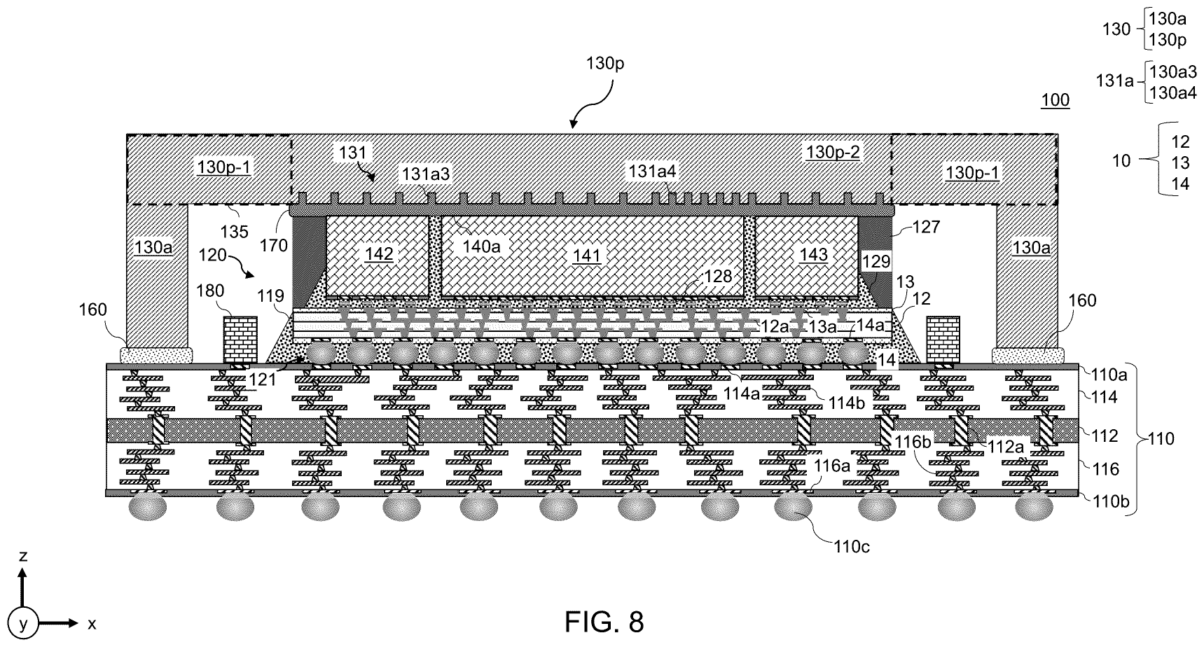

FIG. 8 is a vertical cross-sectional view of a package structure 100 having a second alternative design, according to one or more embodiments. As illustrated in FIG. 8, in the second alternative design, the recessed portions 131 may have a varying concentration in the patterned bottom surface 131. In particular, the recessed portions 131 may include third recessed portions 131a3 having a first concentration and fourth recessed portions 131a4 having a second concentration greater than the first concentration. In at least one embodiment, the second concentration may be in a range from 1.1 to 2.0 times the first concentration. While FIG. 8 illustrates the third recessed portions 131a3 and fourth recessed portions 131a4 in various positions of the package lid 130, both the third recessed portions 131a3 and fourth recessed portions 131a4 may be located in different positions on the package lid 130. Moreover, there may be multiple regions of the third recessed portions 131a3 and fourth recessed portions 131a4 located in a variety of positions within the package lid 130. For example, there may be two areas in which the fourth recessed portions 131a4 may be located having a greater concentration of recessed portions.

The fourth recessed portions 131a4 may provide a greater contact area between the package lid plate portion 130p and the TIM layer 170. Therefore, the patterned bottom surface 131 may be designed so that the fourth recessed portions 131a4 are located on an area of the package module 120 generating more heat compared to other areas of the package module 120.

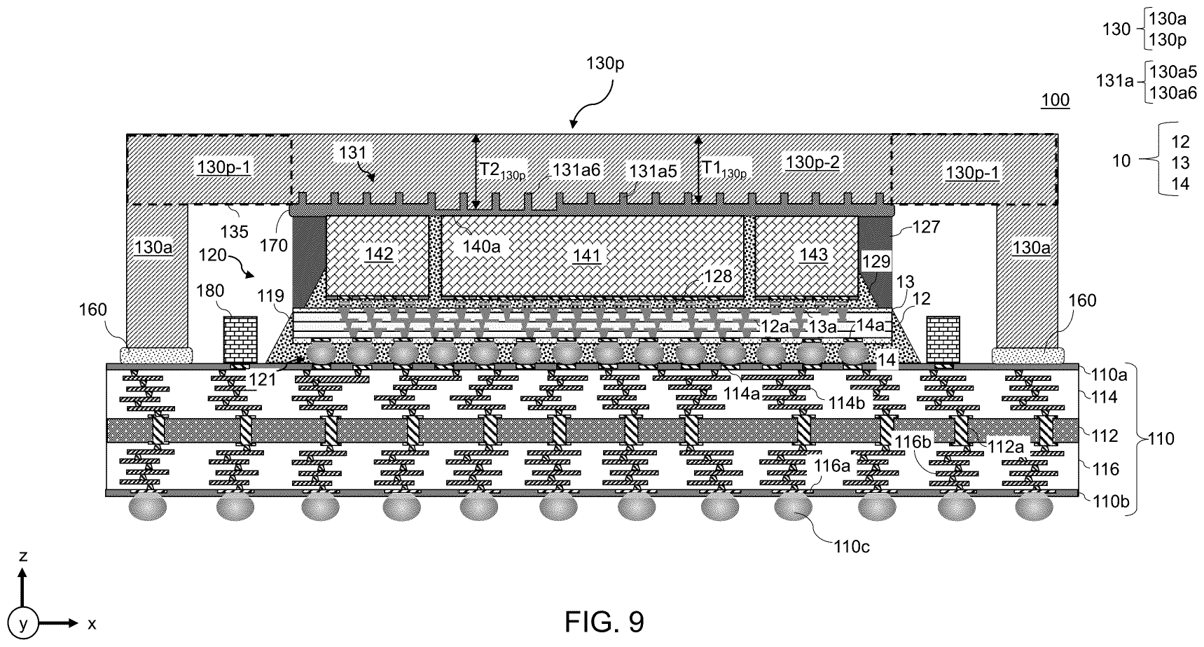

FIG. 9 is a vertical cross-sectional view of a package structure 100 having a third alternative design, according to one or more embodiments. As illustrated in FIG. 9, in the third alternative design, the package lid plate portion 130p may have a first thickness T1₁₃₀ₚ and a second thickness T2₁₃₀ₚ that is greater than the first thickness T1₁₃₀ₚ. In at least one embodiment, the second thickness T2₁₃₀ₚ may be in a range from 1.1 to 2.0 times the first thickness T1₁₃₀ₚ. The recessed portions 131 may include fifth recessed portions 131a5 in the first thickness T1₁₃₀ₚ of the package lid plate portion 130p and sixth recessed portions 131a6 in the second thickness T2₁₃₀ₚ of the package lid plate portion 130p.

The sixth recessed portions 131a6 may provide a greater contact area between the package lid plate portion 130p and the TIM layer 170. Therefore, the patterned bottom surface 131 may be designed so that the sixth recessed portions 131a6 are located on an area of the package module 120 generating more heat compared to other areas of the package module 120.

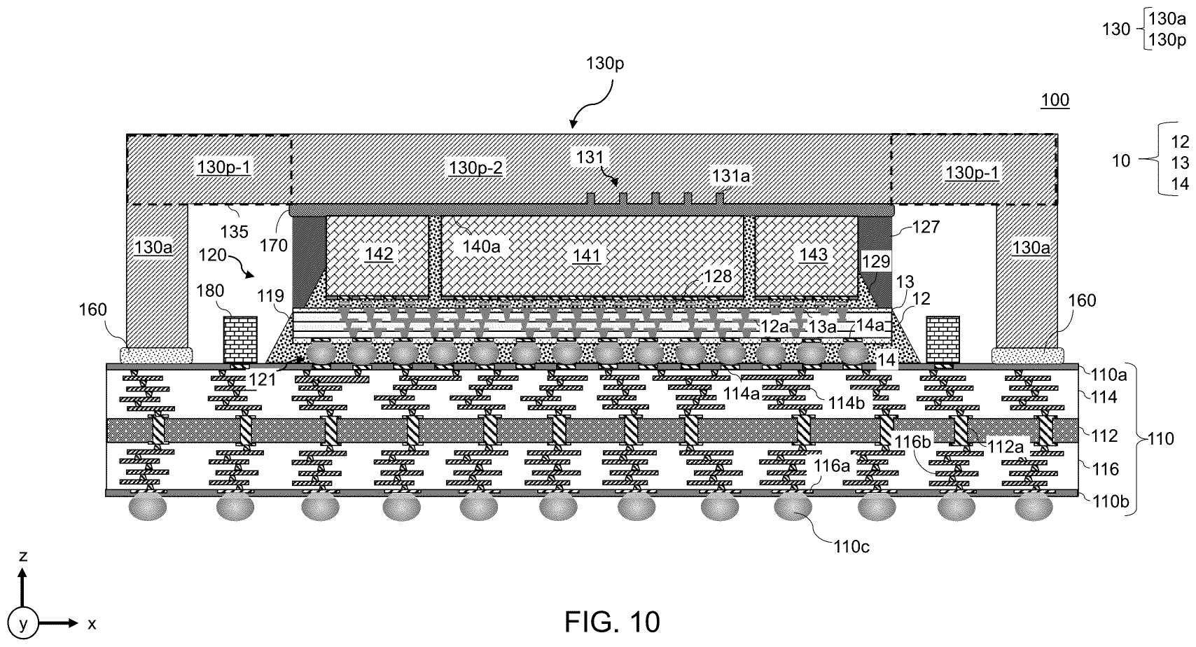

FIG. 10 is a vertical cross-sectional view of a package structure 100 having a fourth alternative design, according to one or more embodiments. As illustrated in FIG. 10, in the fourth alternative design, the patterned bottom surface 131 may include a localized patterned bottom surface 131 located on only a portion of the package module 120 (e.g., in only a portion of the inner package lid plate portion 130p-2). The package lid plate portion 130p may be designed so that the localized patterned bottom surface 131 may be located on an area of the package module 120 generating more heat compared to other areas of the package module 120.

Referring now to FIGS. 1A-10, a package structure 100 may include a package substrate 110, a package module 120 on the package substrate 110, a thermal interface material (TIM) layer 170 on the package module 120, and a package lid 130 on the TIM layer 170. The package lid 130 may include a package lid foot portion 130a attached to the package substrate 110, and a package lid plate portion 130p on the package lid foot portion 130a and including a patterned bottom surface 131 having a plurality of recessed portions 131a, wherein at least a portion of the TIM layer 170 may be located in the plurality of recessed portions 131a.

In one embodiment, the TIM layer 170 may include one of a polymer-based phase change material or a low-melting-temperature metal. In one embodiment, the TIM layer 170 may have a first thickness at the plurality of recessed portions 131a and a second thickness less than the first thickness outside the plurality of recessed portions 131a, and the first thickness may be in a range from 50 μm to 1000 μm. In one embodiment, a ratio of a depth of the plurality of recessed portions 131a to the first thickness of the TIM layer 170 may be in a range from 0.2 to 0.8. The plurality of recessed portions 131a may be substantially filled by the TIM layer 170. In one embodiment, a width of the plurality of recessed portions 131a may be in a range from 100 μm to 1000 μm. In one embodiment, the plurality of recessed portions 131a may be arranged in staggered array having a plurality of columns 132, wherein the plurality of recessed portions 131a within a column 132 of the plurality of columns 132 may be separated by a distance in a range from 100 μm to 1000 μm. In one embodiment, the column 132 of the plurality of columns 132 may be separated from an adjacent column of the plurality of columns 132 by a distance in a range from 100 μm to 1000 μm. In one embodiment, a concentration of the plurality of recessed portions 131a may vary over the patterned bottom surface 131. In one embodiment, the plurality of recessed portions 131a may include one of a hexagon shape, a round shape, and oval shape, a capsule shape, a rounded rectangular, a square shape, a rectangular shape, a triangular shape, a trapezoid shape and a diamond shape. In one embodiment, the package structure 100 may further include a surface mount device (SMD) 180 attached to the package substrate 110 between the package lid foot portion 130a and the package module 120. In one embodiment, the SMD 180 may include one of a rectifier, capacitor or voltage regulator. In one embodiment, an outermost recessed portion 131ao of the plurality of recessed portions 131a may be located over the package module 120. In one embodiment, a distance between an outer sidewall of the package module 120 and the outermost recessed portion 131ao may be in a range from 0.5 mm to 1.0 mm.

Referring again to FIGS. 1A-10, a method of forming a package structure 100 may include forming a package lid 130 including a package lid foot portion 130a and a package lid plate portion 130p on the package lid foot portion 130a, wherein the package lid plate portion 130p may include a patterned bottom surface 131 having a plurality of recessed portions 131a, attaching a package module 120 to a package substrate 110, placing a thermal interface material (TIM) layer 170 on the package module 120, and attaching the package lid 130 to the package substrate 110 such that the package lid plate portion 130p may be on the package module 120 and the TIM layer 170 may be formed in the plurality of recessed portions 131a.

In one embodiment, the attaching of the package lid 130 to the package substrate 110 may include pressing the patterned bottom surface 131 of the package lid plate portion 130p onto the TIM layer 170 such that the plurality of recessed portions 131a may be substantially filled with the TIM layer 170. In one embodiment, the forming of the package lid 130 may include forming a width of the plurality of recessed portions 131a to be in a range from 100 μm to 1000 μm. In one embodiment, the forming of the package lid 130 may include forming the plurality of recessed portions 131a to be arranged in staggered array having a plurality of columns 132, wherein the plurality of recessed portions 131a within a column of the plurality columns may be separated by a distance in a range from 100 μm to 1000 μm. In one embodiment, the forming of the package lid 130 may include forming the column 132 of the plurality of columns to be separated from an adjacent column 132 of the plurality of columns 132 by a distance in a range from 100 μm to 1000 μm.

Referring again to FIGS. 1A-10, a package structure 100 may include a package substrate 110, a package module 120 on the package substrate 110, a package lid 130 over the package module 120, including a plate portion 130p having a bottom surface 131 including recessed structures 131a, a foot portion 130a connected to the plate portion 130p and attached to the package substrate 110, and a thermal interface material (TIM) layer 170 between the package module 120 and the bottom surface 131 of the plate portion 130p.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a package substrate;
a package module on the package substrate;
a thermal interface material (TIM) layer on the package module; and
a package lid on the TIM layer, comprising:
a package lid foot portion attached to the package substrate; and
a package lid plate portion including a patterned bottom surface having a plurality of recessed portions, wherein at least a portion of the TIM layer is located in the plurality of recessed portions.

2. The package structure of claim 1, wherein the TIM layer comprises one of a polymer-based phase change material or a low-melting-temperature metal.

3. The package structure of claim 1, wherein the TIM layer has a first thickness at the plurality of recessed portions and a second thickness less than the first thickness outside the plurality of recessed portions, and the first thickness is in a range from 50 μm to 1000 μm.

4. The package structure of claim 3, wherein a ratio of a depth of the plurality of recessed portions to the first thickness of the TIM layer is in a range from 0.2 to 0.8.

5. The package structure of claim 1, wherein the plurality of recessed portions are substantially filled by the TIM layer.

6. The package structure of claim 1, wherein a width of the plurality of recessed portions is in a range from 100 μm to 1000 μm.

7. The package structure of claim 1, wherein the plurality of recessed portions are arranged in staggered array having a plurality of columns, wherein the plurality of recessed portions within a column of the plurality of columns are separated by a distance in a range from 100 μm to 1000 μm.

8. The package structure of claim 7, wherein the column of the plurality of columns is separated from an adjacent column of the plurality of columns by a distance in a range from 100 μm to 1000 μm.

9. The package structure of claim 1, wherein a concentration of the plurality of recessed portions varies over the patterned bottom surface.

10. The package structure of claim 1, wherein the plurality of recessed portions comprises one of a hexagon shape, a round shape, and oval shape, a capsule shape, a rounded rectangular shape, a square shape, a rectangular shape, a triangular shape, a trapezoid shape and a diamond shape.

11. The package structure of claim 1, further comprising:
a surface mount device (SMD) attached to the package substrate between the package lid foot portion and the package module.

12. The package structure of claim 11, wherein the SMD comprises one of a rectifier, capacitor or voltage regulator.

13. The package structure of claim 1, wherein an outermost recessed portion of the plurality of recessed portions is located over the package module.

14. The package structure of claim 13, wherein a distance between an outer sidewall of the package module and the outermost recessed portion is in a range from 0.5 mm to 1.0 mm.

15. A method of forming a package structure, comprising:
forming a package lid comprising a package lid foot portion and a package lid plate portion on the package lid foot portion, wherein the package lid plate portion comprises a patterned bottom surface having a plurality of recessed portions;
attaching a package module to a package substrate;
placing a thermal interface material (TIM) layer on the package module; and
attaching the package lid to the package substrate such that the package lid plate portion is on the package module and at least a portion of the TIM layer is disposed in the plurality of recessed portions.

16. The method of claim 15, wherein the attaching of the package lid to the package substrate comprises pressing the patterned bottom surface of the package lid plate portion onto the TIM layer such that the plurality of recessed portions are substantially filled with the TIM layer.

17. The method of claim 15, wherein the forming of the package lid comprises forming a width of the plurality of recessed portions to be in a range from 100 μm to 1000 μm.

18. The method of claim 15, wherein the forming of the package lid comprises forming the plurality of recessed portions to be arranged in staggered array having a plurality of columns, wherein the plurality of recessed portions within a column of the plurality of columns are separated by a distance in a range from 100 μm to 1000 μm.

19. The method of claim 18, wherein the forming of the package lid comprises forming the column of the plurality of columns to be separated from an adjacent column of the plurality of columns by a distance in a range from 100 μm to 1000 μm.

20. A package structure, comprising:
a package substrate;
a package module on the package substrate;
a package lid over the package module, comprising:
a plate portion having a bottom surface including recessed structures; and
a foot portion connected to the plate portion and attached to the package substrate; and
a thermal interface material (TIM) layer between the package module and the bottom surface of the plate portion.
